(19) United States
(12) Patent Application Publication
(10) Pub. No.: US 2025/0324560 A1
(43) Pub. Date: Oct. 16, 2025

(54) SEMICONDUCTOR DEVICE STRUCTURE AND METHODS OF FORMING SAME

(71) Applicant: TAIWAN SEMICONDUCTOR MANUFACTURING COMPANY, LTD., Hsinchu (TW)

(72) Inventors: Jui-Lin CHEN, Taipei (TW); Chung-Te LIEN, Taoyuan (TW); Shih-Che LIN, Hsinchu (TW); Chih-Hsiang HUANG, Hsinchu (TW); Fu-Kai YANG, Hsinchu (TW); Lien-Jung HUNG, Taipei (TW)

(21) Appl. No.: 18/634,949

(22) Filed: Apr. 14, 2024

(51) Int. Cl. H10B 10/00; H01L 29/06; H01L 29/417; H01L 29/423; H01L 29/66; H01L 29/775; H01L 29/786

(52) U.S. Cl. CPC H10B 10/125; H10D 30/014; H10D 30/43; H10D 30/6729; H10D 30/6735; H10D 30/6757; H10D 62/121

(57) ABSTRACT

A method includes forming first and second semiconductor fins on a front side of a substrate, removing portions of the first and second semiconductor fins to expose first and second substrate portions, respectively, forming a first source/drain region over the first substrate portion, wherein the first source/drain region comprises an n-type epitaxial material, forming a second source/drain region over the second substrate portion, wherein the second source/drain region comprises a p-type epitaxial material, depositing a dielectric material over the first and second source/drain regions, forming an opening in the dielectric material to expose a portion of the first source/drain region and a portion of the second source/drain region, forming a mask on the exposed portion of the first source/drain region, performing an implantation process to implant a dopant in the second source/drain region, removing the mask, and depositing a conductive contact electrically connected to the first and second source/drain regions.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a circuit diagram of a six transistor (6T) static random-access memory (SRAM) cell, in accordance with some embodiments.

FIGS. 2-6 are perspective views of various stages of manufacturing a semiconductor device structure, in accordance with some embodiments.

FIGS. 7-18 are cross-sectional side views of various stages of manufacturing the semiconductor device structure taken along line A-A of FIG. 6, in accordance with some embodiments.

FIGS. 19-25 are cross-sectional side views of various stages of manufacturing the semiconductor device structure taken along line B-B of FIG. 6, in accordance with some embodiments.

FIGS. 26-30 are cross-sectional side views of various alternative stages of manufacturing the semiconductor device structure taken along line B-B of FIG. 6, in accordance with some other embodiments.

FIGS. 31-35 are cross-sectional side views of various alternative stages of manufacturing the semiconductor device structure taken along line B-B of FIG. 6, in accordance with some other embodiments.

FIGS. 36-40 are cross-sectional side views of various alternative stages of manufacturing the semiconductor device structure taken along line B-B of FIG. 6, in accordance with some other embodiments.

FIGS. 41-42 are a cross-sectional side view taken along line A-A of FIG. 6 and a schematic top view, respectively, of the semiconductor device structure after formation of conductive contacts (see FIG. 24), in accordance with some embodiments.

FIGS. 43-44 are schematic top views of alternative high density and high current cells, respectively, of the semiconductor device structure of FIG. 42, in accordance with some embodiments.

FIGS. 45-47 are schematic top views of alternative implant boundaries of the semiconductor device structure of FIG. 42, in accordance with some embodiments.

FIGS. 48-50 are cross-sectional side views of various stages of a backside process of manufacturing the semiconductor device structure taken along line A-A of FIG. 6, in accordance with some embodiments.

FIG. 51 is a cross-sectional side view of another stage of the semiconductor device structure taken along line A-A of FIG. 6, in accordance with some embodiments.

FIG. 52 illustrates test results for channel resistance and drain-induced barrier loading for different implantation depths, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments to be described below relate generally to implanting a dopant (e.g., a p-type dopant such as boron) into a source/drain region of a static random-access memory (SRAM) p-type metal-oxide semiconductor (PMOS) to achieve lower contact resistance in source/drain formation (e.g., via higher concentration of boron (B) in epi layer), to improve pull-up (PU) transistor performance, and to increase each of sigma (i.e., minimum amount of variation for DC read/write failure), SRAM read margin, and Vmax. In contrast, weak PU transistor performance can degrade Vmax (e.g., lower Vmax pass rate), and higher resistance can cause poor epitaxy coverage, which can negatively impact device performance.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

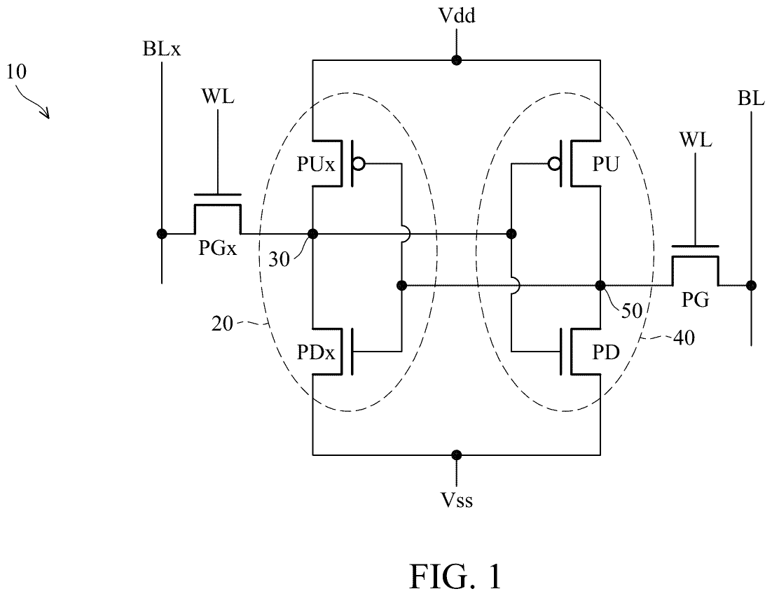

FIG. 1 is a circuit diagram of a six transistor (6T) SRAM cell 10, in accordance with some embodiments. The SRAM cell 10 includes a first inverter 20 formed by a pull-up transistor PUx and a pull-down transistor PDx. The SRAM cell 10 further includes a second inverter 40 formed by a pull-up transistor PU and a pull-down transistor PD. Furthermore, both the first inverter 20 and second inverter 40 are coupled between a voltage bus Vdd and a ground potential Vss. In some embodiments, the pull-up transistors PUx and PU can be p-type metal oxide semiconductor (PMOS) transistors while the pull-down transistors PDx and PD can be n-type metal oxide semiconductor (NMOS) transistors, and the claimed scope of the present disclosure is not limited in this respect.

In FIG. 1, the first inverter 20 and the second inverter 40 are cross-coupled. That is, the first inverter 20 has an input connected to the output of the second inverter 40. Likewise, the second inverter 40 has an input connected to the output of the first inverter 20. The output of the first inverter 20 is referred to as a storage node 30. Likewise, the output of the second inverter 40 is referred to as a storage node 50. In a normal operating mode, the storage node 30 is in the opposite logic state as the storage node 50. By employing the two cross-coupled inverters, the SRAM cell 10 can hold the data using a latched structure so that the stored data will not be lost without applying a refresh cycle as long as power is supplied through Vdd.

In an SRAM device using the 6T SRAM cells, the cells are arranged in rows and columns. The columns of the SRAM array are formed by a bit line pairs, namely a first bit line BLx and a second bit line BL. The cells of the SRAM device are disposed between the respective bit line pairs. As shown in FIG. 1, the SRAM cell 10 is placed between the bit line BLx and the bit line BL.

In FIG. 1, the SRAM cell 10 further includes a first pass-gate transistor PGx connected between the bit line BLx and the storage node 30 of the first inverter 20. The SRAM cell 10 further includes a second pass-gate transistor PG connected between the bit line BL and the storage node 50 of the second inverter 40. The gates of the first pass-gate transistor PGx and the second pass-gate transistor PG are connected to a word line WL, which connects SRAM cells in a row of the SRAM array.

In operation, if the pass-gate transistors PGx and PG are inactive, the SRAM cell 10 will maintain the complementary values at storage nodes 30 and 50 indefinitely as long as power is provided through Vdd. This is so because each inverter of the pair of cross coupled inverters drives the input of the other, thereby maintaining the voltages at the storage nodes. This situation will remain stable until the power is removed from the SRAM, or a write cycle is performed, changing the stored data at the storage nodes.

In the circuit diagram of FIG. 1, the pull-up transistors PUx, PU are p-type transistors. The pull-down transistors PDx, PD, and the pass-gate transistors PGx, PG are n-type transistors. According to various embodiments, the pull-up transistors PUx, PU, the pull-down transistors PDx, PD, and the pass-gate transistors PGx, PG can be implemented by nanostructure channel FETs.

The structure of the SRAM cell 10 in FIG. 1 is described in the context of the 6T-SRAM. One of ordinary skill in the art, however, should understand that features of the various embodiments described herein may be used for forming other types of devices, such as an 8T-SRAM memory device, or memory devices other than SRAMs. Furthermore, embodiments of the present disclosure may be used as stand-alone memory devices, memory devices integrated with other integrated circuitry, or the like. Accordingly, the embodiments discussed herein are illustrative of ways to make and use the disclosure, and do not limit the scope of the disclosure.

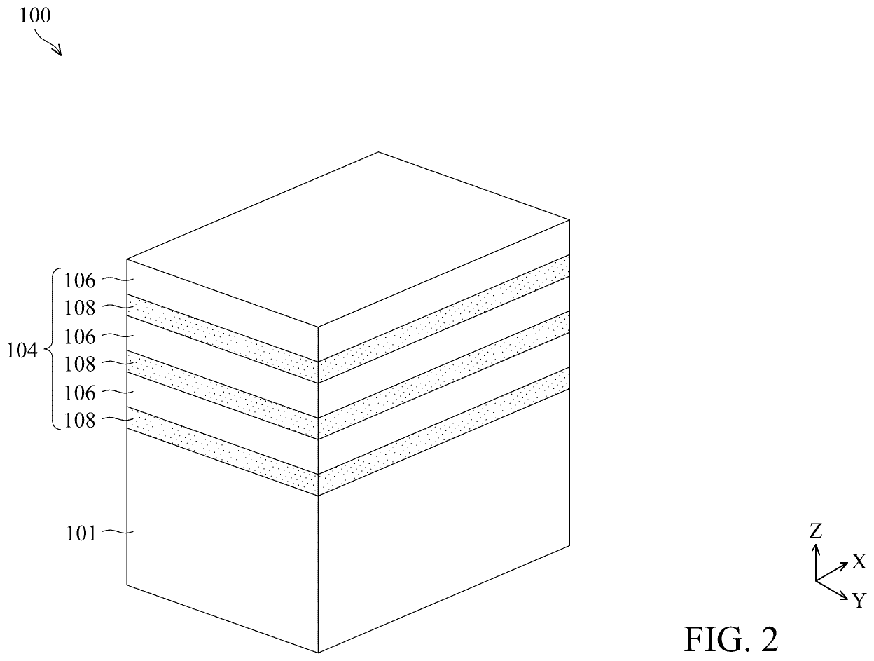

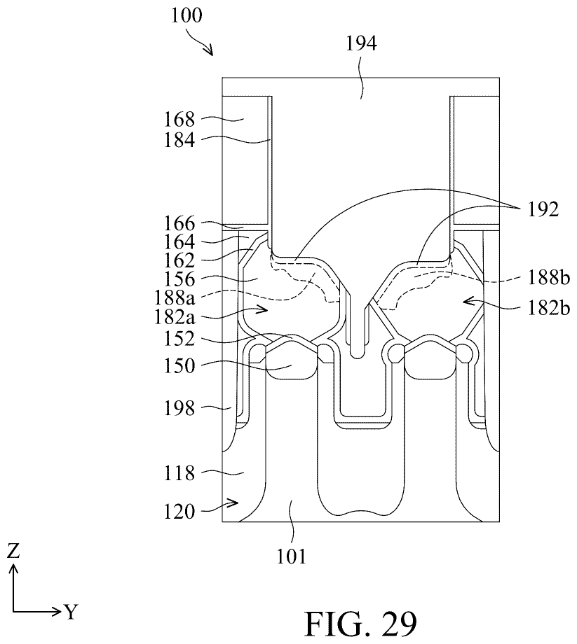

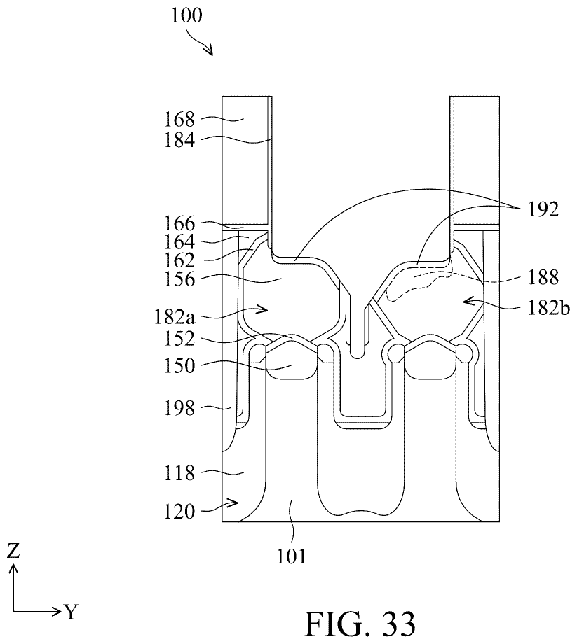

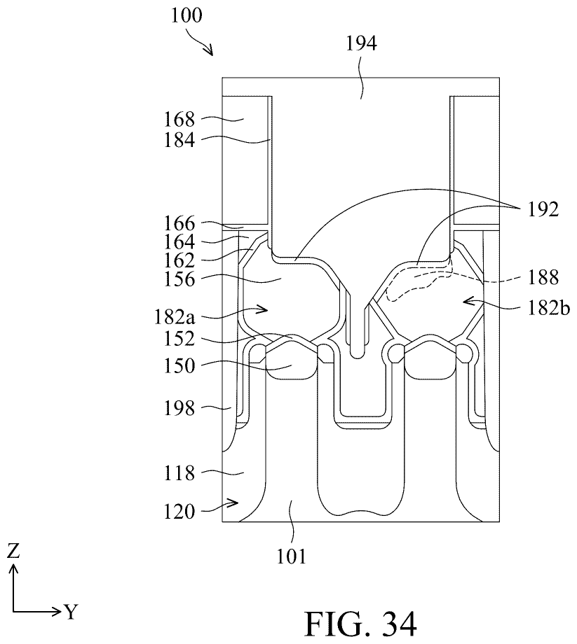

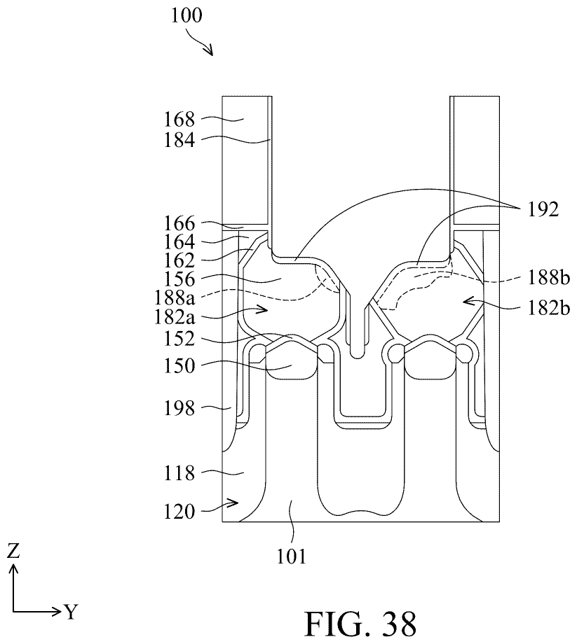

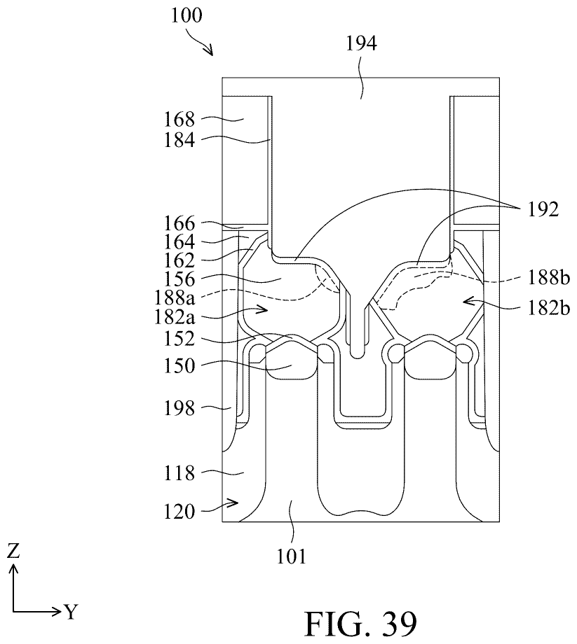

FIGS. 2-51 show exemplary processes for manufacturing a semiconductor device structure 100 according to embodiments of the present disclosure. It is understood that additional operations can be provided before, during, and after processes shown by FIGS. 2-51, and some of the operations described below can be replaced or eliminated, for additional embodiments of the method. The order of the operations/processes is not limiting and may be interchangeable. The semiconductor device structure 100 may include one or more components of the SRAM cell 10 of FIG. 1.

FIGS. 2-6 are perspective views of various stages of manufacturing a semiconductor device structure 100, in accordance with some embodiments. As shown in FIG. 2, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GaAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 2, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. In some embodiments, the stack of semiconductor layers 104 includes two first semiconductor layers 106. In some embodiments, the stack of semiconductor layers 104 includes three first semiconductor layers 106. In some embodiments, the stack of semiconductor layers 104 includes four first semiconductor layers 106.

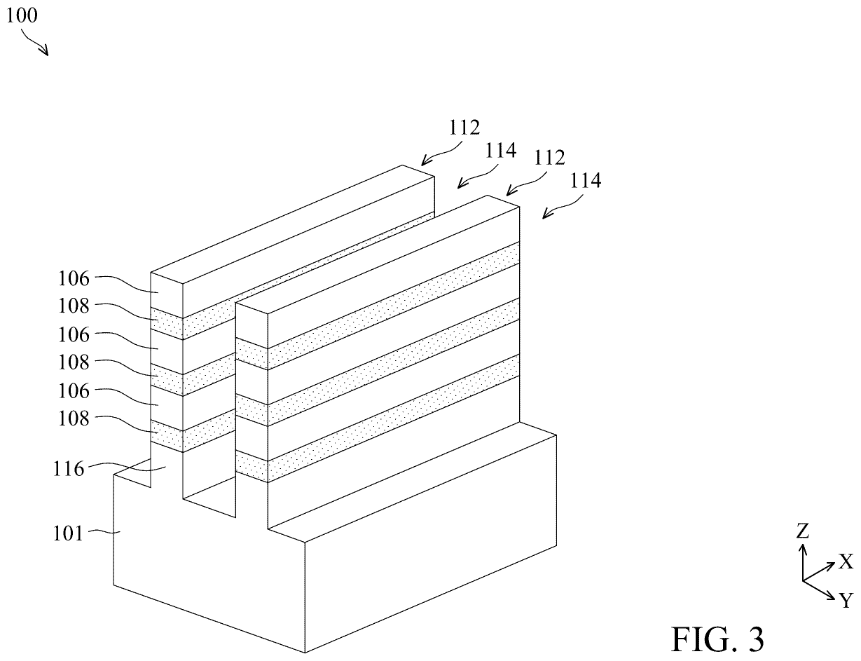

As shown in FIG. 3, fin structures 112 are formed from the stack of semiconductor layers 104. The fin structures 112 may be semiconductor fins. Each fin structure 112 has an upper portion including the semiconductor layers 106, 108 and a well portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (c-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

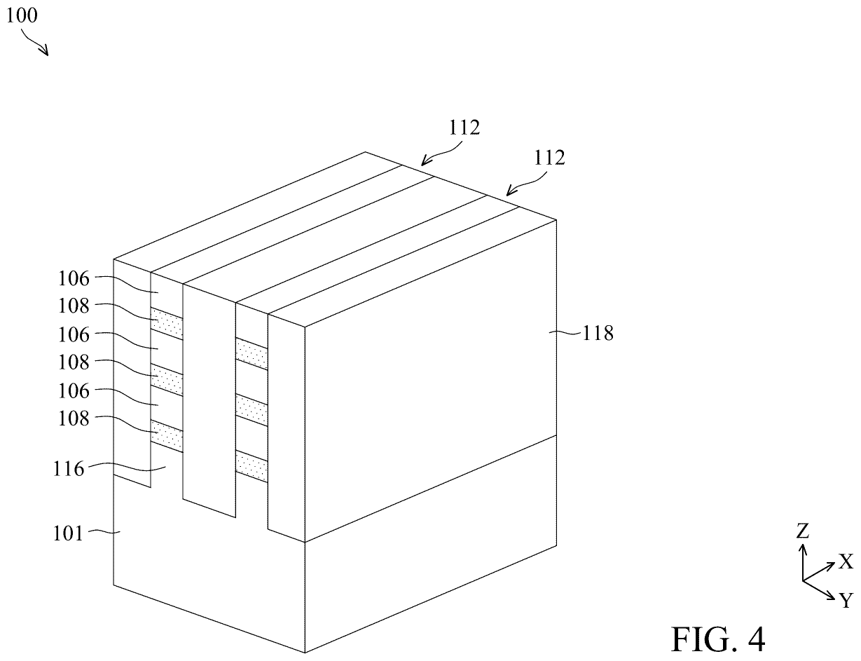

As shown in FIG. 4, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

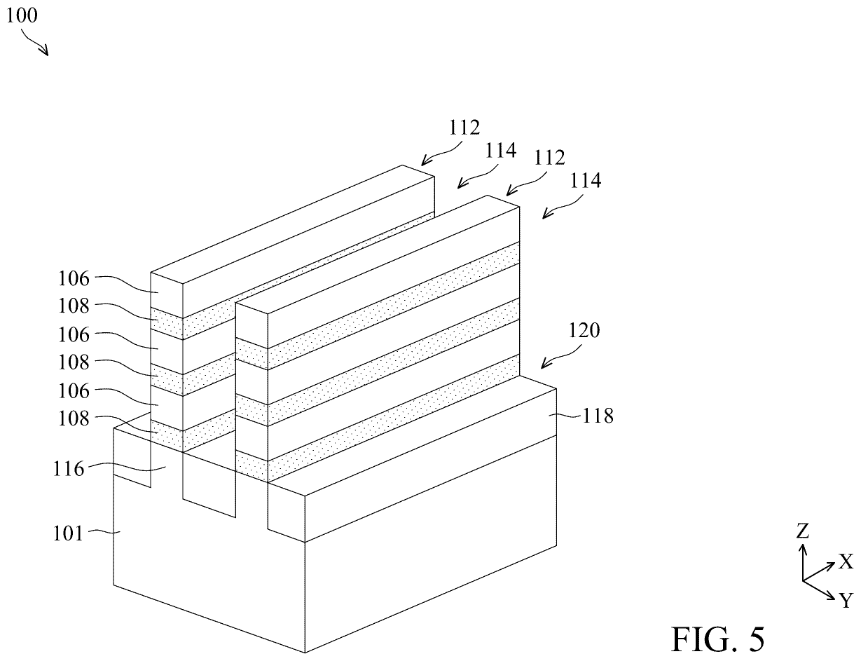

As shown in FIG. 5, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the well portion 116 formed from the substrate 101. In some embodiments, the isolation regions 120 are the shallow trench isolation (STI) regions.

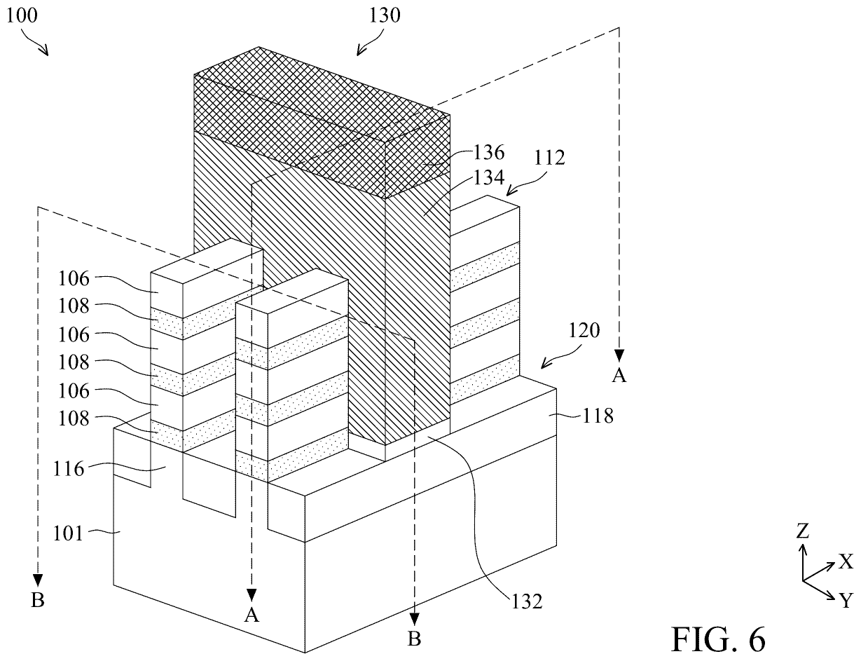

As shown in FIG. 6, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The portions of the fin structures 112 that are covered by the sacrificial gate electrode layer 134 of the sacrificial gate structure 130 serve as channel regions for the semiconductor device structure 100.

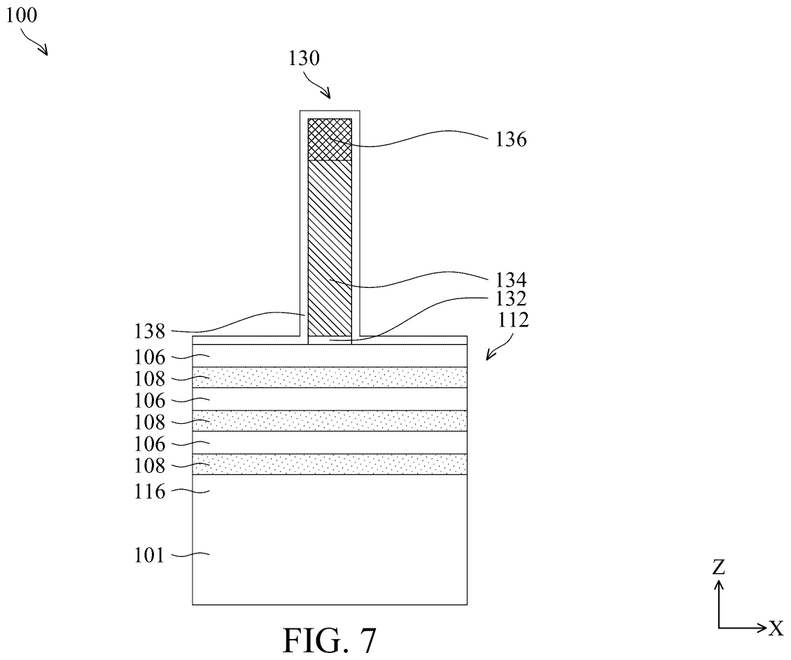

FIGS. 7-18 are cross-sectional side views of various stages of manufacturing the semiconductor device structure 100 taken along line A-A of FIG. 6, in accordance with some embodiments. As shown in FIG. 7, a first gate spacer 138 is deposited on the exposed surfaces of the semiconductor device structure 100. For example, the first gate spacer 138 is deposited on the fin structures 112, the isolation regions 120, and the sacrificial gate structure 130. The first gate spacer 138 may be made of a dielectric material such as silicon oxide, silicon nitride, silicon carbide, silicon oxynitride, SiCN, silicon oxycarbide, SiCON, and/or combinations thereof. The first gate spacer 138 may be formed by any suitable process. In some embodiments, the first gate spacer 138 is a conformal layer formed by a conformal process, such as an atomic layer deposition (ALD) process.

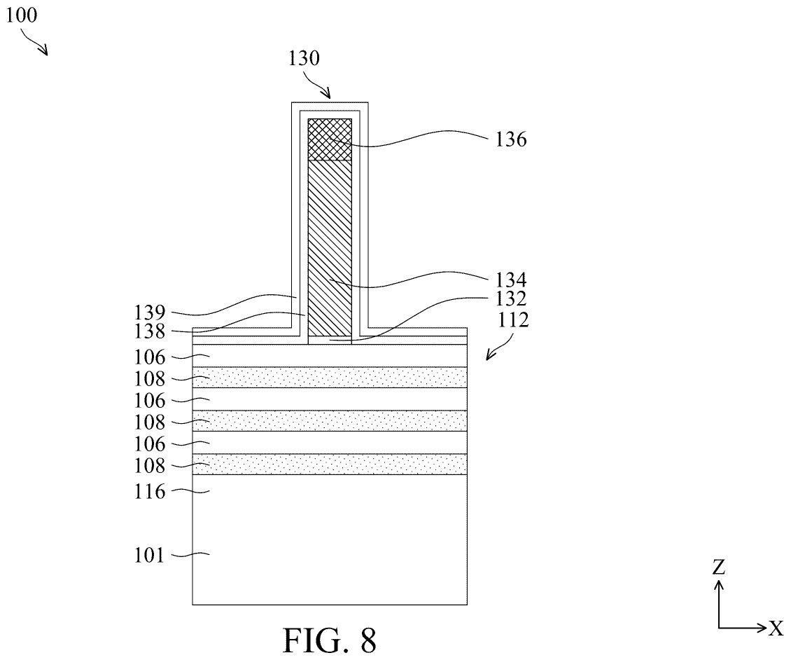

As shown in FIG. 8, a second gate spacer 139 is deposited on the first gate spacer 138. The second gate spacer 139 may include any suitable dielectric material, such as SiOₓ, SiON, SiN, SiCON, or SiCO. The second gate spacer 139 may have a thickness ranging from about 0.5 nm to about 5 nm. The second gate spacer 139 may be formed by any suitable process. In some embodiments, the second gate spacer 139 is deposited by CVD, PECVD, or electron cyclotron resonance CVD (ECR-CVD).

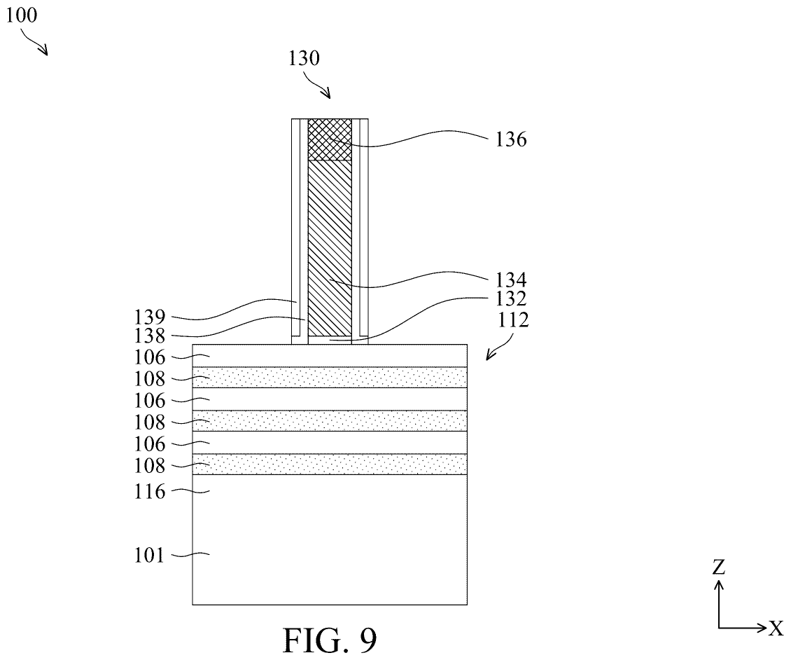

As shown in FIG. 9, horizontal portions of the first and second gate spacers 138, 139 are removed. In some embodiments, the horizontal portions of the first and second gate spacers 138, 139 are removed by an anisotropic etch process. The anisotropic etch process may be a selective etch process that does not substantially affect the mask layer 136, the stack of semiconductor layers 104, and the isolation regions 120.

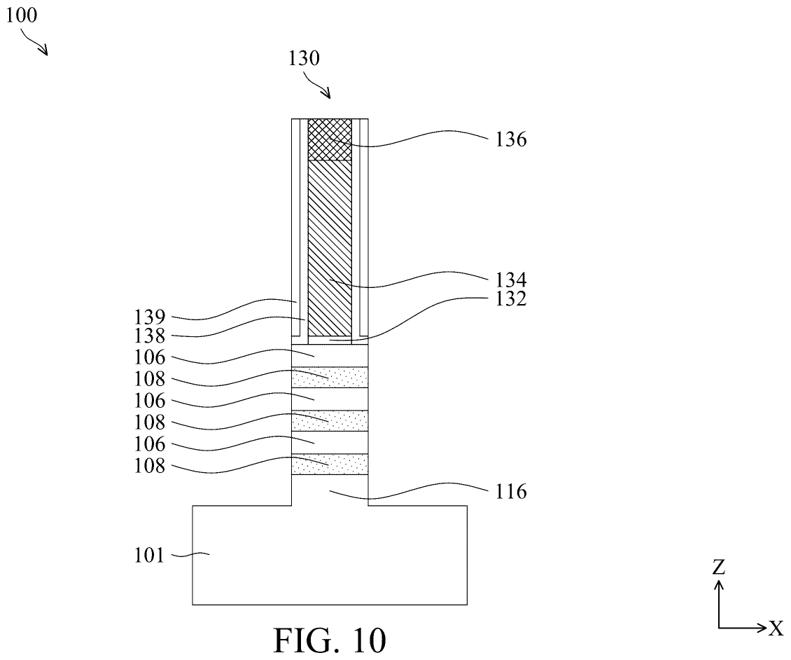

As shown in FIG. 10, the portions of the fin structures 112 not covered by the sacrificial gate structure 130 and the first and second gate spacers 138, 139 are recessed to a level above, at, or below the top surfaces of the isolation regions 120. The recess of the portions of the fin structures 112 can be done by an etch process. The etch process may be a dry etch, such as a RIE, NBE, or the like, or a wet etch, such as using tetramethylammonium hydroxide (TMAH), ammonium hydroxide (NH₄OH), or any suitable etchant. The well portions 116 are exposed on opposite sides of the sacrificial gate structure 130, as shown in FIG. 10.

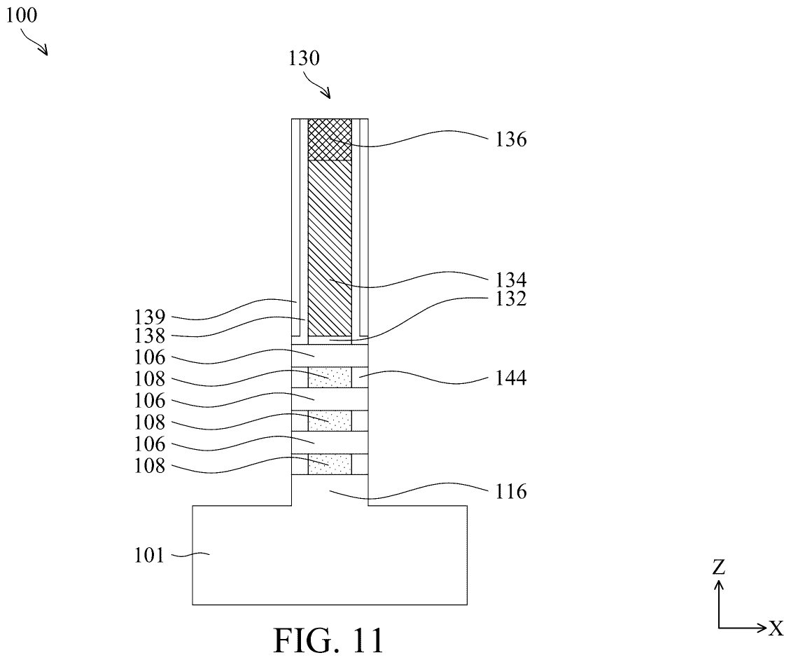

As shown in FIG. 11, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

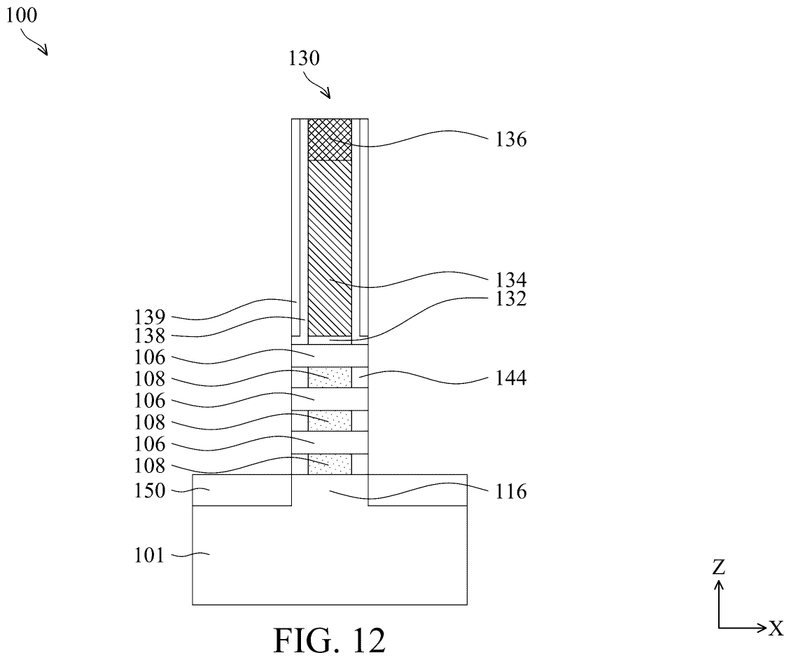

As shown in FIG. 12, a first semiconductor material 150 is formed on the exposed well portions 116. In some embodiments, the first semiconductor material 150 includes undoped silicon or undoped SiGe. The first semiconductor material 150 may be first formed on semiconductor surfaces, such as on the exposed well portions 116 and on the first semiconductor layers 106, by epitaxy. A subsequent etch process is performed to remove the portions of the first semiconductor material 150 formed on the first semiconductor layers 106. The first semiconductor material 150 formed on the exposed well portions 116 may form a concave top surface as the result of the etch process. In some embodiments, the first semiconductor material 150 has a thickness ranging from about 5 nm to about 50 nm along the Z direction.

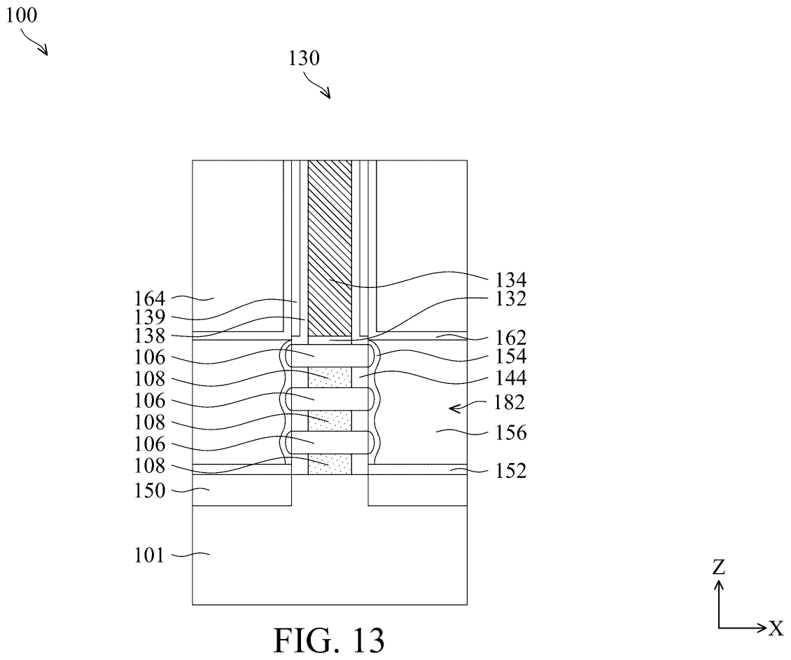

Next, as shown in FIG. 13, a dielectric layer 152 is formed on the first semiconductor material 150. The dielectric layer 152 may be formed by first forming a dielectric layer on the exposed surfaces of the semiconductor device structure 100, followed by one or more etch processes to remove portions of the dielectric layer other than the dielectric layer 152. A mask layer (not shown), such as a bottom anti-reflective coating (BARC) layer, may be used to assist with the removal of the portions of the dielectric layer. The dielectric layer 152 may include any suitable dielectric material. In some embodiments, the dielectric layer 152 includes SiN. The dielectric layer 152 may be formed by any suitable process. In some embodiments, the dielectric layer 152 is formed by CVD. Next, a second semiconductor material 154 is formed from the first semiconductor layers 106. The second semiconductor material 154 may be made of one or more layers of Si, SiP, SiC, SiAs, SiSb, and SiCP for n-channel FETs or Si, SiGe, Ge for p-channel FETs. For p-channel FETs, p-type dopants, such as boron (B), may be included in the second semiconductor material 154. For n-channel FETs, n-type dopants, such as phosphorus (P) or arsenic (As), may be included in the second semiconductor material 154. In some embodiments, the dopant concentration of the second semiconductor material 154 may range from about 1×10¹⁹ cm⁻³ to about 2×10²¹ cm⁻³. The second semiconductor material 154 may be formed by an epitaxial growth method using CVD, ALD or MBE. As shown in FIG. 13, in some embodiments, the second semiconductor material 154 is a continuous layer over the first semiconductor layers 106 and the dielectric spacers 144. In some embodiments, the second semiconductor material 154 is selectively formed on semiconductor materials, such as the first semiconductor layers 106, and is not formed on dielectric materials, such as the dielectric layer 152 and the dielectric spacers 144. In some embodiments, the second semiconductor material 154 includes facets, which may correspond to crystalline planes of the material used for the first semiconductor layers 106.

Next, as shown in FIG. 13, a third semiconductor material 156 is formed from the second semiconductor material 154. The third semiconductor material 156 may be formed by an epitaxial growth method using CVD, ALD or MBE. The third semiconductor material 156 may be made of one or more layers of Si, SiP, SiC and SiCP for n-type FETs or Si, SiGe, Ge for p-type FETs. For p-type FETs, p-type dopants, such as boron (B), may be included in the second semiconductor material 154. For n-type FETs, n-type dopants, such as phosphorus (P) or arsenic (As), may be included in the third semiconductor material 156. In some embodiments, the second semiconductor material 154 and the third semiconductor material 156 may include the same semiconductor materials but with different dopant concentrations. The dopant concentration of the third semiconductor material 156 may be substantially greater than the dopant concentration of the second semiconductor material 154. In some embodiments, the dopant concentration of the third semiconductor material 156 may range from about 5×10¹⁹ cm⁻³ to about 4×10²¹ cm⁻³. The third semiconductor material 156 may be epitaxially grown from the second semiconductor material 154. The quality of the third semiconductor material 156 may be improved due to the facets of the second semiconductor material 154. In some embodiments, the dielectric layer 152 is not present, and the third semiconductor material 156 is grown from the first semiconductor material 150 and the second semiconductor material 154.

In some embodiments, a cap layer (not shown) may be formed on the third semiconductor material 156. The cap layer may include a semiconductor material. In some embodiments, the cap layer includes the same material as the third semiconductor material. The cap layer may be epitaxially grown from the third semiconductor material 156.

In some embodiments, the second and third semiconductor materials 154, 156 may be in-situ doped during growth. If the dopant concentrations of the second and third semiconductor materials 154, 156 are greater than the above-mentioned respective ranges, the quality of the second and third semiconductor materials 154, 156 may be negatively affected. Thus, subsequent processes may be performed to increase the dopant concentration in order to decrease electrical contact resistance. In other words, during the formation of the second and third semiconductor materials 154, 156 (i.e., epitaxial deposition with in-situ doping), the quality of the and second third semiconductor materials 154, 156 may be negatively affected if the dopant concentrations are greater than the above-mentioned respective ranges. After the formation of the second and third semiconductor materials 154, 156, the dopant concentrations of the second and third semiconductor materials 154, 156 may be increased to a level above the above-mentioned respective ranges to lower the electrical contact resistance without negatively affect the quality of the second and third semiconductor materials 154, 156.

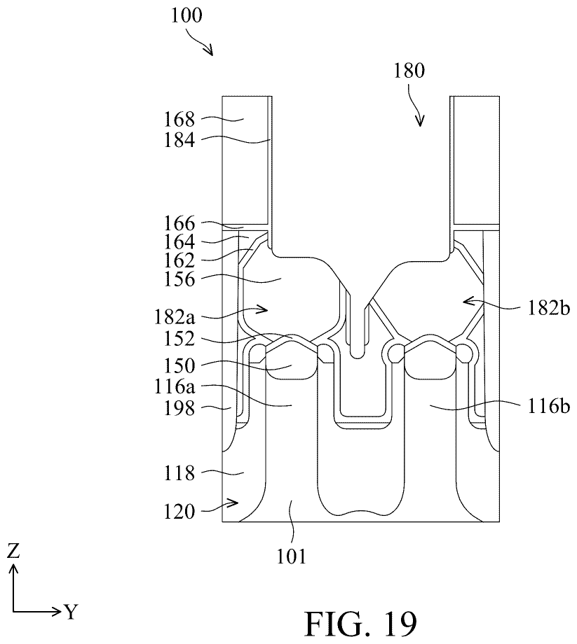

The second semiconductor material 154 and the third semiconductor material 156 together may be the source/drain (S/D) region 182. In this disclosure, a source region and a drain region are interchangeably used, and the structures thereof are substantially the same. Furthermore, source/drain region(s) may refer to a source or a drain, individually or collectively, dependent upon the context. In some embodiments, p-type S/D regions and n-type S/D regions may be formed separately using one or more mask layers. In some embodiments, the second semiconductor material 154 and the third semiconductor material 156 are crystalline semiconductor materials. For example, as described in more detail in connection with FIG. 19, a first S/D region 182a is formed from a first substrate portion (e.g., over the first semiconductor material 150 and over the dielectric layer 152 on a first recessed portion of the fin structures 112). The first S/D region 182a can be an n-type epitaxial material. Continuing this example, a second S/D region 182b is formed from a second substrate portion (e.g., over a second recessed portion of the fin structures 112 that is separated from the first recessed portion by an isolation region 120). The second S/D region 182b can be a p-type epitaxial material.

Next, as shown in FIG. 13, a contact etch stop layer (CESL) 162 is conformally formed on the exposed surfaces of the semiconductor device structure 100. The CESL 162 covers the second gate spacer 139, the isolation regions 120, and the third semiconductor material 156 (or the cap layer if present). The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. In some embodiments, the CESL 162 is a single layer, as shown in FIG. 13. In some embodiments, the CESL 162 includes two or more layers. Next, an interlayer dielectric (ILD) layer 164 is formed on the CESL 162. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164.

After the ILD layer 164 is formed, a planarization operation, such as CMP, is performed on the semiconductor device structure 100 until the sacrificial gate electrode layer 134 is exposed, as shown in FIG. 13.

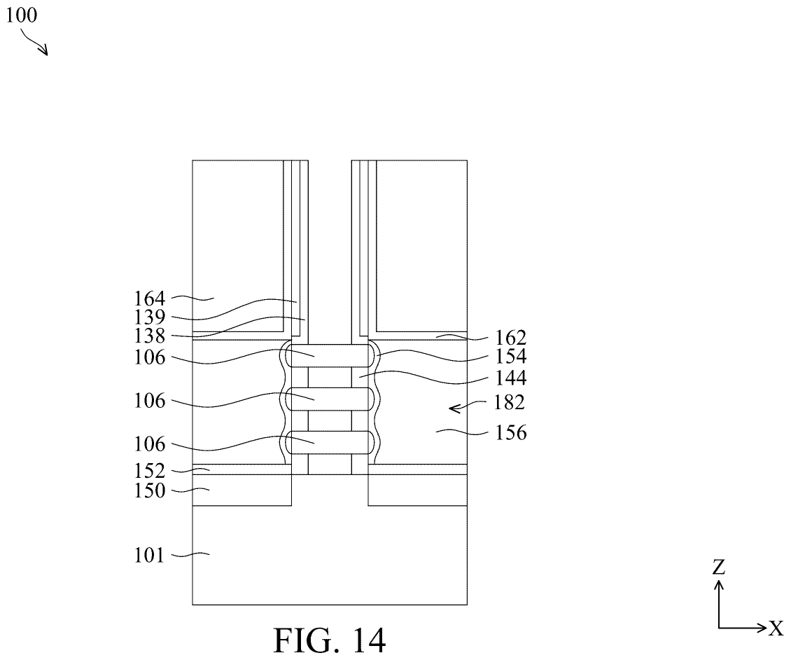

Next, as shown in FIG. 14, the sacrificial gate structure 130 and the second semiconductor layers 108 are removed. The removal of the sacrificial gate structure 130 and the semiconductor layers 108 forms an opening between the first gate spacers 138 and between the first semiconductor layers 106. The ILD layer 164 protects the second semiconductor material 156 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the first gate spacers 138, the ILD layer 164, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the first gate spacers 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), or phosphoric acid (H₃PO₄).

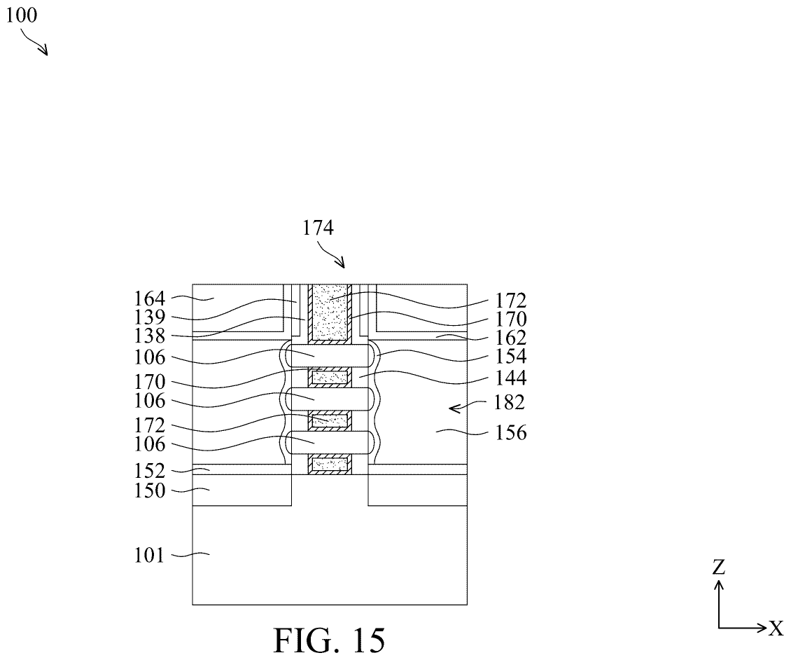

As shown in FIG. 15, after the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106, and one or more work function layers (not shown) are formed between the gate dielectric layer 170 and the gate electrode layer 172. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The work function layer may include polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, or other suitable materials. The gate electrode layer 172 may include one or more layers of conductive material, such as platinum (Pt), palladium (Pd), tantalum (Ta), ytterbium (Yb), aluminum (Al), silver (Ag), titanium (Ti), ruthenium (Ru), molybdenum (Mo), chromium (Cr), tungsten (W), copper (Cu), or similar material, and/or any combinations thereof. The gate electrode layer 172 may be formed by CVD, ALD, electro-plating, or other suitable deposition technique. The gate electrode layer 172 may also be deposited over the upper surface of the ILD layer 164. The gate dielectric layer 170 and the gate electrode layer 172 formed over the ILD layer 164 are then removed by using, for example, CMP, until the top surface of the ILD layer 164 is exposed.

It is understood that the semiconductor device structure 100 may undergo further processes, such as cut metal gate (CMG) process and/or continuous poly on diffusion edge (CPODE) process. The CMG process separates the gate electrode layer 172 into multiple segments that can be individually controlled. The CPODE process forms isolation between devices.

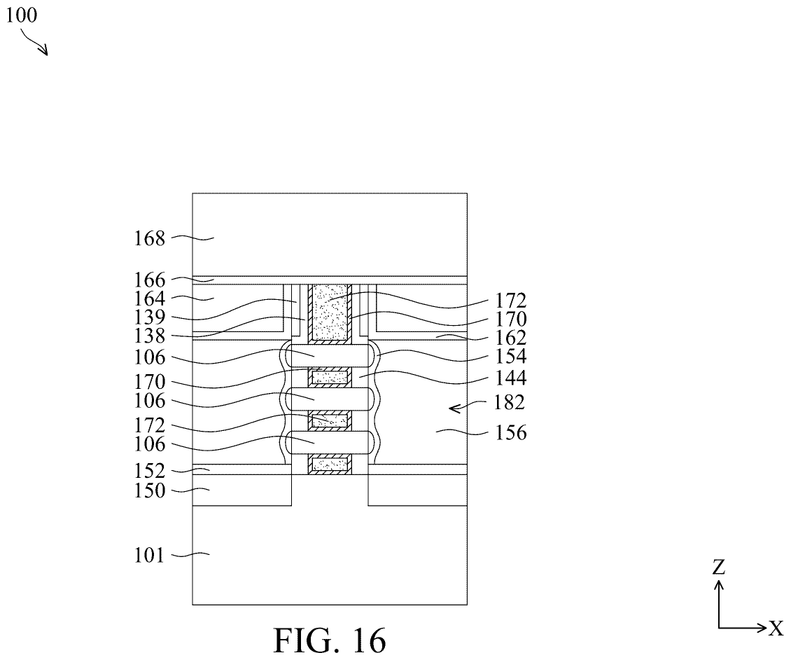

As shown in FIG. 16, an etch stop layer 166 and a second ILD layer 168 are formed over the ILD layer 164 and the gate electrode layer 172. The etch stop layer 166 may include the same material as the CESL 162 and may be formed by the same process as the CESL 162. The second ILD layer 168 may include the same material as the ILD layer 164 and may be formed by the same process as the ILD layer 164.

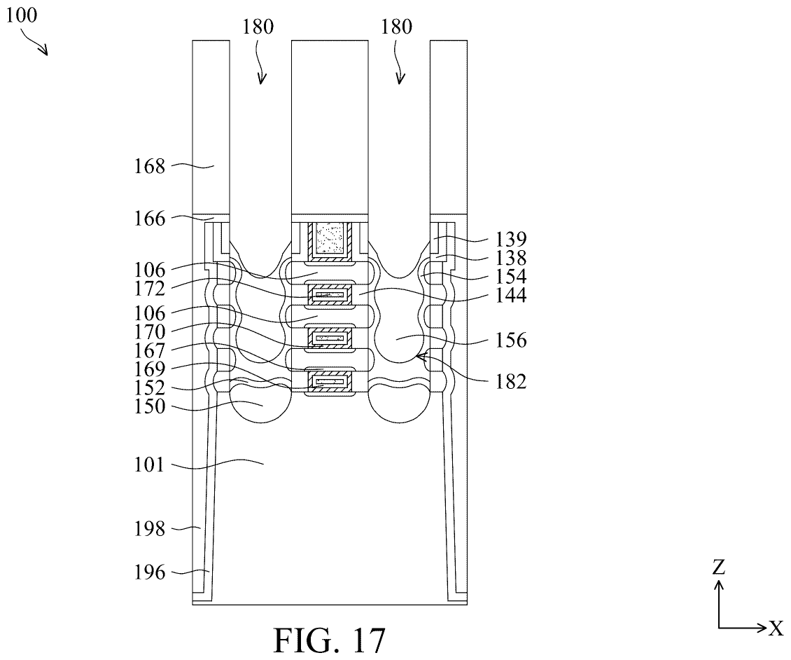

Next, as shown in FIG. 17, openings 180 are formed in the second ILD layer 168, the etch stop layer 166, the ILD layer 164, and the CESL 162 to expose the third semiconductor material 156. In some embodiments, portions of the ILD layer 164 and the CESL 162 located over the third semiconductor material 156 may be removed. In some embodiments, the cap layer (not shown) and a portion of the third semiconductor material 156 may be also removed. The openings 180 may be formed by an etch process, such as a dry etch process, a wet etch process, or a combination thereof. A patterned mask (not shown) may be formed over the second ILD layer 168, and the pattern of the patterned mask is transferred to the second ILD layer 168, the etch stop layer 166, the ILD layer 164, and the CESL 162.

As shown in FIG. 17, the semiconductor device structure 100 includes an IL 167 formed on the first semiconductor layers 106 and a work function layer 169 formed between the gate dielectric layer 170 and the gate electrode layer 172. In addition, the semiconductor device structure 100 includes a dielectric liner 196 and a dielectric material 198. The dielectric liner 196 and the dielectric material 198 may be an isolation structure formed by a CPODE process. In some embodiments, the dielectric material 198 includes the same material as the etch stop layer 166.

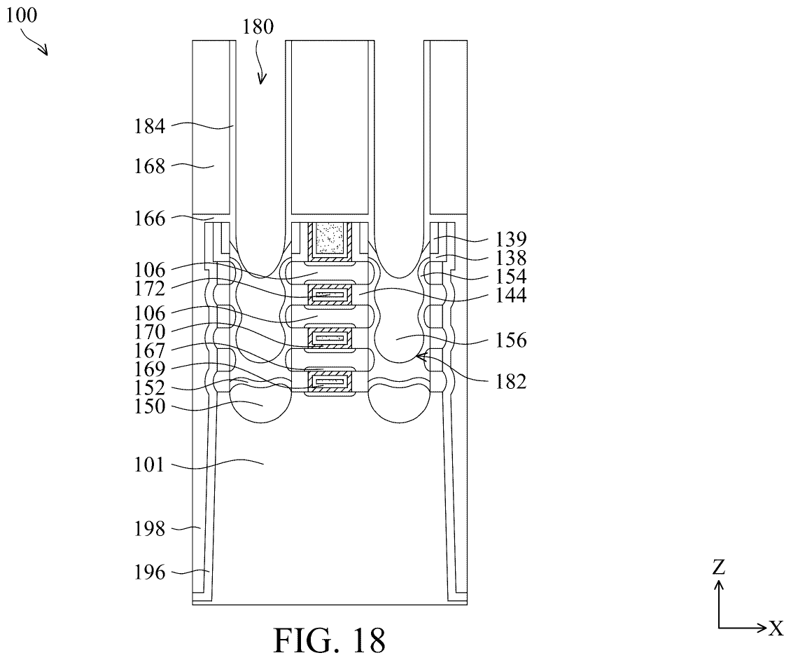

As shown in FIGS. 18, a liner 184 is formed on the vertical surfaces of the second ILD layer 168, the etch stop layer 166, and the first gate spacer 138. The liner 184 may include any suitable material. In some embodiments, the liner 184 is a nitride layer, such as a silicon nitride layer. In some embodiments, the liner 184 includes the same material as the etch stop layer 166. The liner 184 may be formed by first forming a dielectric layer on the exposed surfaces of the semiconductor device structure 100, followed by an anisotropic etch process to remove portions of the dielectric layer formed on horizontal surfaces of the semiconductor device structure 100. For example, portions of the dielectric layer formed on the second ILD layer 168 and the third semiconductor material 156 are removed by the anisotropic etch process. The liner 184 protects the second ILD layer 168 during the subsequent processes.

FIGS. 19-25 are cross-sectional side views of various stages of manufacturing the semiconductor device structure 100 taken along line B-B of FIG. 6, in accordance with some embodiments. FIG. 19 illustrates the semiconductor device structure 100 at the same stage of manufacturing as the semiconductor device structure 100 shown in FIG. 18. As shown in FIG. 19, in some embodiments, the opening 180 exposes both the first S/D region 182a, which may be an n-type epitaxial material, and the second S/D region 182b, which may be a p-type epitaxial material. In some embodiments, the first S/D region 182a is formed over a first well portion 116a. In some embodiments, the second S/D region 182b is formed over a second well portion 116b.

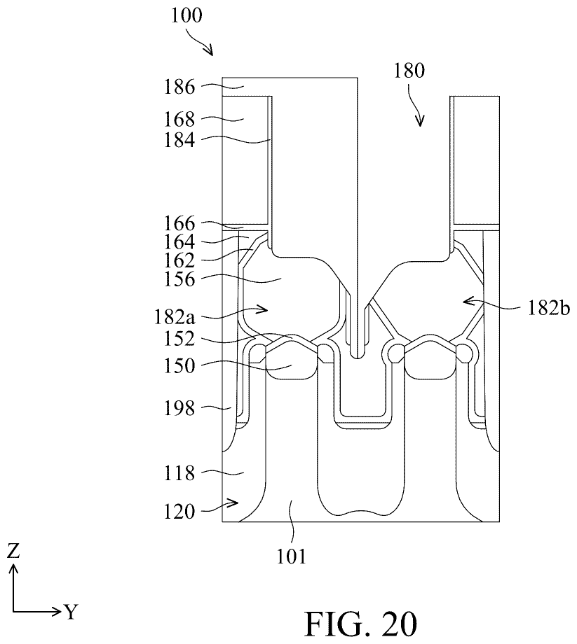

As shown in FIG. 20, a mask 186 is formed on the exposed portion of the first S/D region 182a. The mask 186 may be formed by any suitable process, such as a photo-lithography process. In some embodiments, the photo-lithography process may include forming a photoresist layer, exposing the photoresist layer to a pattern, performing post-exposure bake processes, and developing the photoresist layer to form a mask including the photoresist layer. In some embodiments, patterning the photoresist layer to form the mask may be performed using an electron beam (e-beam) lithography process.

As shown in FIG. 20, in some embodiments, the mask 186 covers the entire exposed portion of first S/D region 182a and the mask 186 does not cover any part of the exposed portion of the second S/D region 182b. The border of the mask 186 is between the first S/D region 182a and the second S/D region 182b. As shown, the mask 186 extends beyond the first S/D region 182a from the ILD layer 168 to the border between the first S/D region 182a and the second S/D region 182b. In some other embodiments, the mask 186 may not extend past the first S/D region 182a. In some embodiments, the mask 186 is completely covering the exposed portion of the first S/D region 182a and thereby protecting the first S/D region 182a from a subsequently performed implantation process.

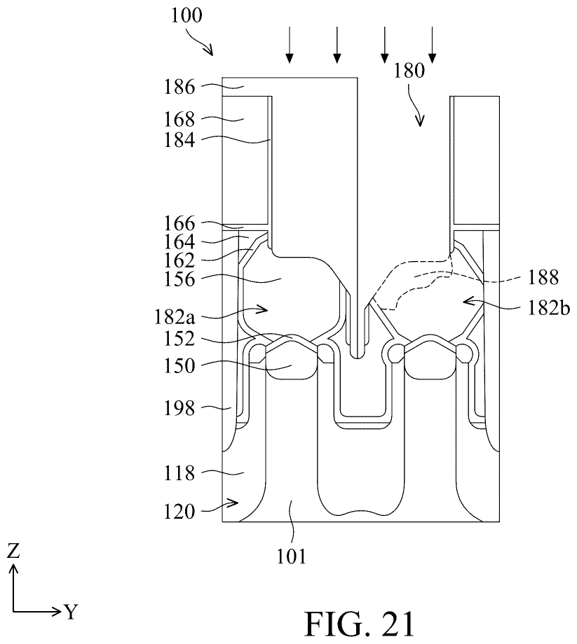

In some embodiments, in order to reduce the electrical contact resistance, one or more processes may be performed to increase dopant concentration in the third semiconductor material 156 and/or the second semiconductor material 154. As shown in FIG. 21, an implantation process is performed to implant a dopant in the second S/D region 182b to form a doped region 188 in the second S/D region 182b. In some embodiments, the dopant is a p-type dopant, such as boron. In some embodiments, the boron isotope composition resulting from the implantation process includes 100% ¹¹B, which is superior to the boron isotope composition in a common p-type epitaxial S/D region, which is closer to ¹⁰B:¹¹B ratio of 20%: 80%. The implantation process may have an implantation energy ranging from about 0.3 keV to about 60 keV, a dosage greater than about 1×10¹³ cm⁻², and a processing temperature ranging from about −150 degrees Celsius to about 500 degrees Celsius. In some embodiments, the implantation process forms the doped region 188 in the second S/D region 182b without doping the first S/D region 182a. The mask 186 can prevent protected regions underneath the mask 186 from being doped, while unprotected regions outside the area of the mask 186 are doped. In other words, the doped region 188 can correspond to the pattern of the mask 186. The depth and concentration of the doped region 188 may be controlled as described in more detail below.

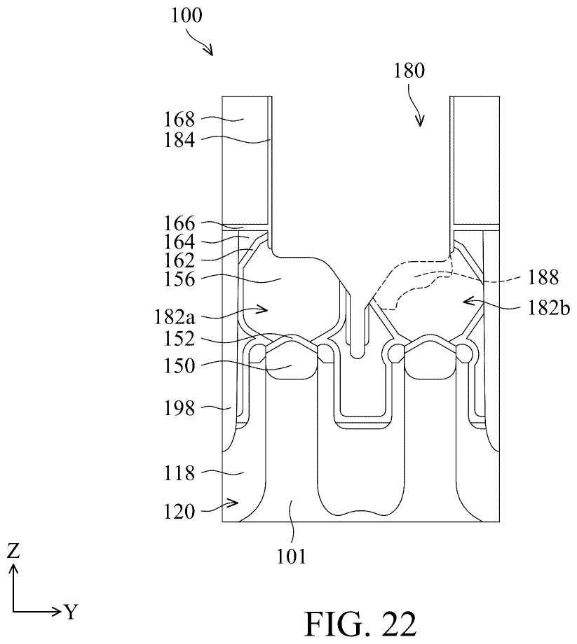

As shown in FIG. 22, the mask 186 is removed. The mask 186 may be removed by any suitable process. In some embodiments, the mask 186 may be removed by a wet stripping process or a plasma ashing process. The wet stripping process or the plasma ashing process can be used to selectively remove the mask 186 but not substantially affect the ILD layer 168, the first S/D region 182a, the second S/D region 182b, and the liner 184.

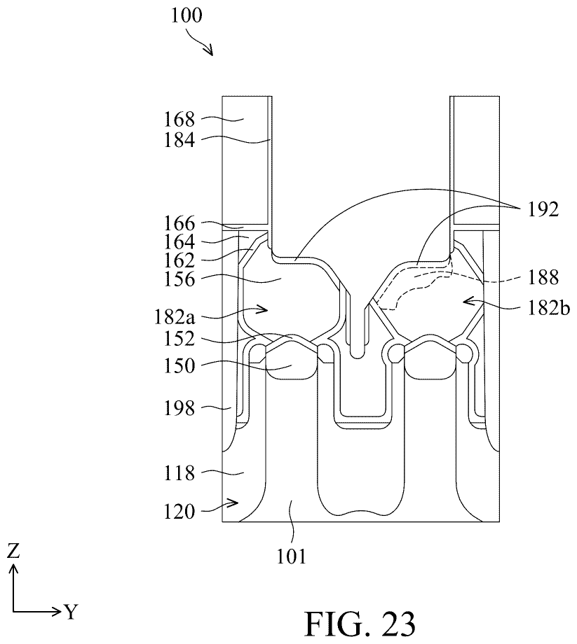

As shown in FIG. 23, silicide layers 192 are formed on the exposed portions of the first S/D region 182a and the second S/D region 182b. The silicide layer 192 may be formed by any suitable process. In some embodiments, a metal layer (not shown) is first formed on the semiconductor device structure 100. The metal layer may include Ti, Ni, Ru, Co, W, or other suitable metal. In some embodiments, the metal layer is a multi-layer structure. The multi-layer structure may include a metal layer and a metal nitride or metal oxide layer. The metal layer may be deposited by any suitable process, such as ALD, CVD, or PVD. After the metal layer deposition, an annealing process is performed to react the third semiconductor material 156 with the metal layer, thereby forming the silicide layers 192. The silicide layer 192 may include any suitable material, such as NiSi, TiSi, CoSi, RuSi, or wSi.

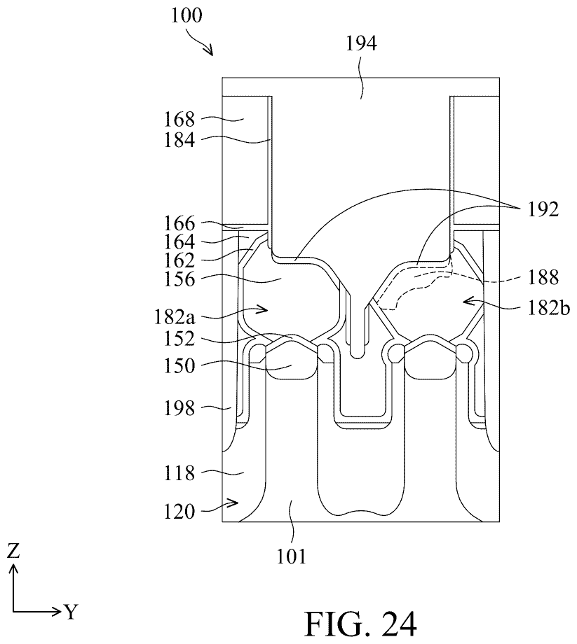

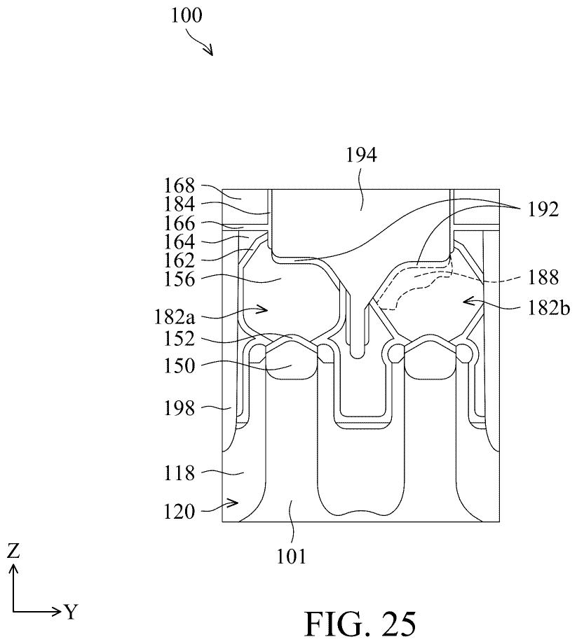

As shown in FIG. 24, a conductive contact 194 is deposited in the opening 180. The conductive contact 194 is electrically connected to the first S/D region 182a and the second S/D region 182b. The conductive contact 194 may be electrically conductive and may include a material having one or more of Ru, Mo, Co, Ni. W, Ti, Ta, Cu, Al, TiN or TaN. The conductive contact 194 may be formed by any suitable method, such as electro-chemical plating (ECP), or PVD. As shown in FIG. 25, a planarization operation, such as a CMP method, is performed.

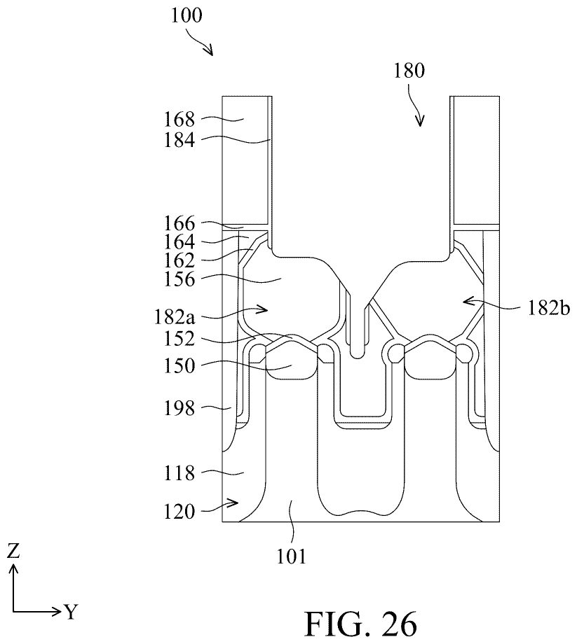

FIGS. 26-30 are cross-sectional side views of various alternative stages of manufacturing the semiconductor device structure taken along line B-B of FIG. 6, in accordance with some other embodiments. FIGS. 26-30 can include aspects described in connection with FIGS. 20-25, without limitation. FIG. 26 corresponds with the stage shown in FIG. 20. However, as shown in FIG. 26, instead of forming a mask on the exposed portion of the first S/D region 182a, the exposed portion of the first S/D region 182a is left exposed and unprotected to the implantation process that follows. Without a mask, there is not any part of the exposed portions of either the first S/D region 182a or the second S/D region 182b that is covered or protected from implantation.

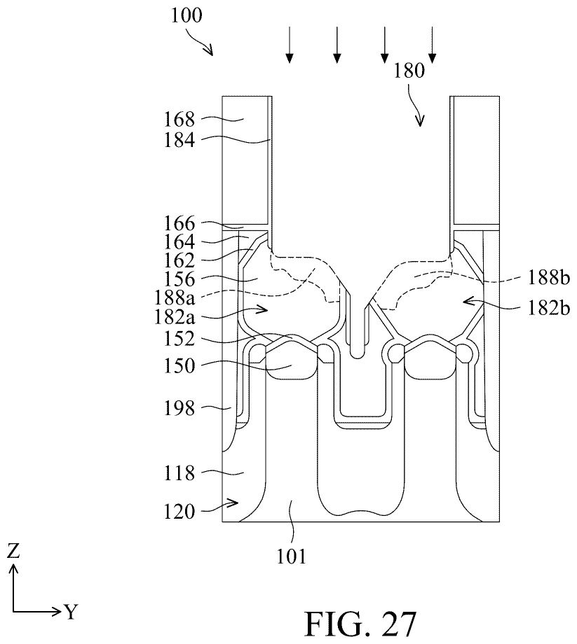

FIG. 27 corresponds with the stage shown in FIG. 21. However, as shown FIG. 27, because the implantation process is performed without having the mask over the first S/D region 182a, the dopant is implanted in both the exposed portion of the first S/D region 182a, to form a first doped region 188a, and the exposed portion of the second S/D region 182b, to form a second doped region 188b. In some embodiments, the first doped region 188a and the second doped region 188b may receive equivalent doping from the implantation process. In some embodiments, the first doped region 188a includes a p-type dopant in an n-type semiconductor material, and the second doped region 188b includes the p-type dopant in a p-type semiconductor material. As described above, the dopant is a p-type dopant, which may reduce contact resistance of the p-type second S/D region 182b and may negatively affect the n-type first S/D region 182a. In some embodiments, the first S/D region 182a is a part of the pull-down transistor PDx of the SRAM cell 10 shown in FIG. 1, and the second S/D region 182b is a part of the pull-up transistor PUx of the SRAM cell 10 shown in FIG. 1. In some embodiments, the benefit from the reduced contact resistance from the pull-up transistor PUx outweighs the drawback of the negatively affected pull-down transistor PDx. In other words, in some embodiments, it is more important to reduce the contact resistance of the pull-up transistor PUx, while a slight increase in the contact resistance of the pull-down transistor PDx does not substantially affect the operation of the SRAM cell 10. Thus, in some embodiments, the mask 186 is not formed, which has benefits of decreased process time and cost.

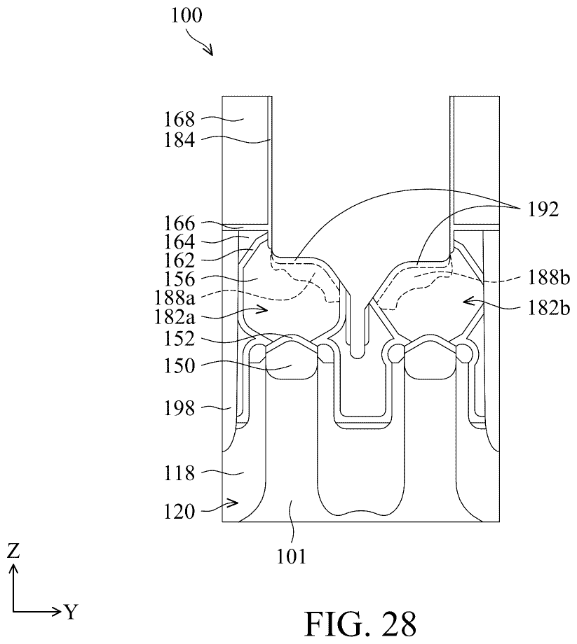

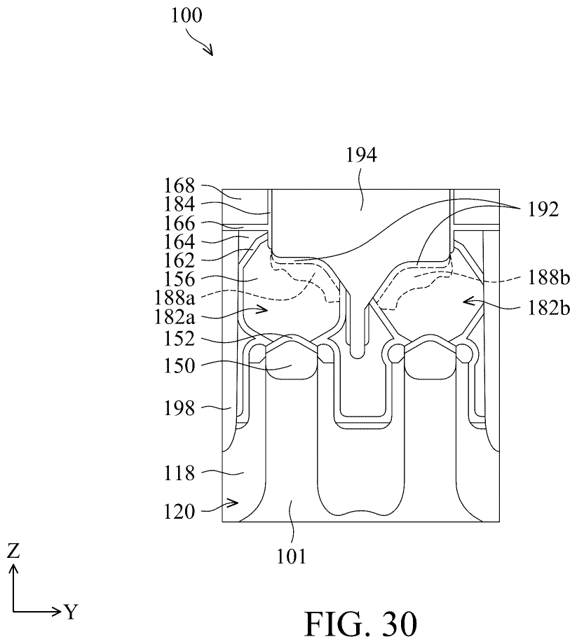

FIGS. 28-30 correspond to FIGS. 23-25, respectively, including formation of the silicide layers 192, formation of the conductive contact 194, and the planarization operation. Thus, the final structure shown in FIG. 30 differs from FIG. 25 by the existence of the first doped region 188a.

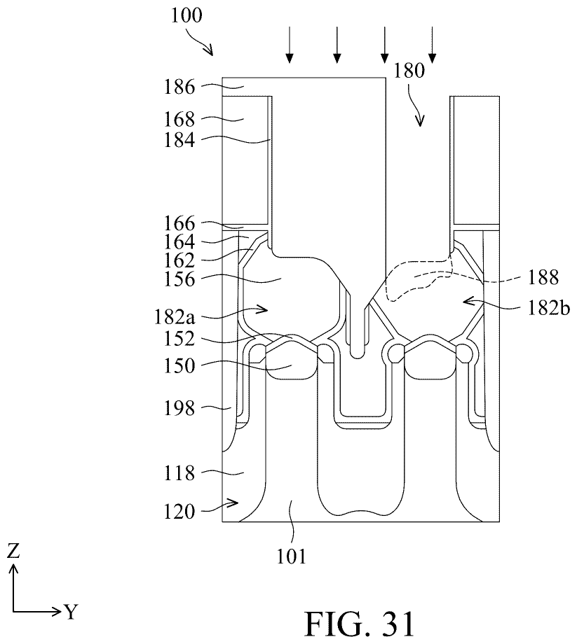

FIGS. 31-35 are cross-sectional side views of various alternative stages of manufacturing the semiconductor device structure taken along line B-B of FIG. 6, in accordance with some other embodiments. FIGS. 31-35 can include aspects described in connection with FIGS. 20-25, without limitation. FIG. 31 corresponds with the stage shown in FIGS. 20-21. However, as shown in FIG. 31, the mask 186 is formed on part of the exposed portion of the second S/D region 182b, in addition to covering the entire exposed portion of first S/D region 182a. Thus, only part of the exposed portion of the second S/D region 182b is not covered by the mask 186 and left unprotected. In some embodiments, in order to make sure that the first S/D region 182a is covered by the mask 186, a portion of the second S/D region 182b is also covered by the mask 186. The border of the mask 186 is over the second S/D region 182b. In some embodiments, the border may be located such that the mask 186 covers less than 90 percent of a total width (along the Y-direction) of the exposed portion of the second S/D region 182b, such as less than 70 percent, such as less than 50 percent, such as less than 30 percent, such as less than 10 percent of the total width. As shown, the mask 186 extends beyond the first S/D region 182a from the ILD layer 168 to the border over the second S/D region 182b. In some embodiments, the mask 186 is completely covering the exposed portion of the first S/D region 182a and part of the second S/D region 182b and thereby protecting the first S/D region 182a and part of the second S/D region 182b from implantation. As shown FIG. 31, because the mask 186 is expanded to cover part of the exposed portion of the second S/D region 182b, the doped region 188 is smaller in width. In such embodiment, the smaller doped region 188 can reduce the contact resistance, while the first S/D region 182a is not doped with the dopant by the implantation process. In other words, the risk of negatively affecting the first S/D region 182a is reduced, while the benefit of reduced contact resistance for the second S/D region 182b is not substantially diminished. The depth and concentration of the doped region 188 may be controlled as described in more detail below.

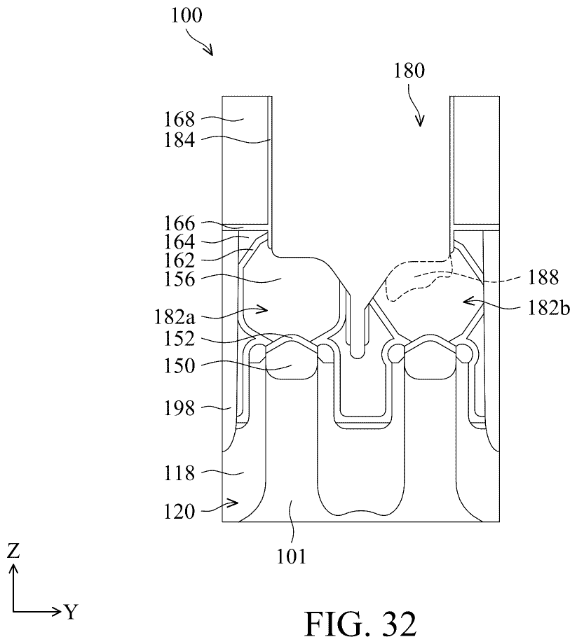

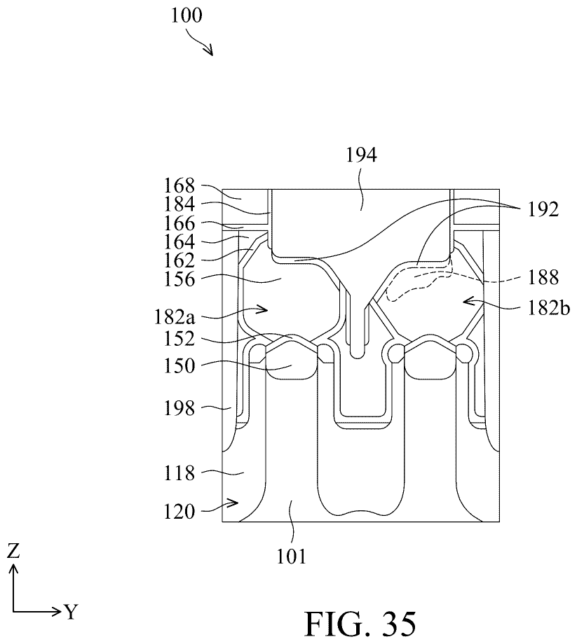

FIGS. 32-35 correspond to FIGS. 22-25, respectively, including removal of the mask 186, formation of the silicide layers 192, formation of the conductive contact 194, and the planarization operation. Thus, the final structure shown in FIG. 35 differs from FIG. 25 by the smaller doped region 188.

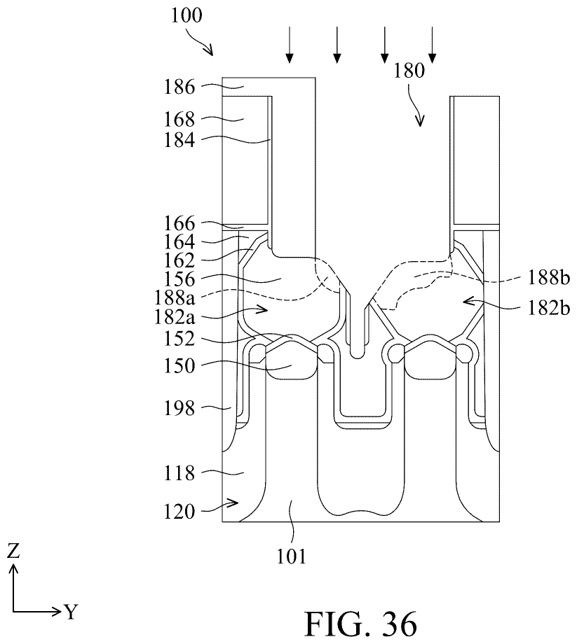

FIGS. 36-40 are cross-sectional side views of various alternative stages of manufacturing the semiconductor device structure taken along line B-B of FIG. 6, in accordance with some other embodiments. FIGS. 36-40 can include aspects described in connection with FIGS. 20-25, without limitation. FIG. 36 corresponds with the stage shown in FIGS. 20-21. However, as shown in FIG. 36, the mask 186 is formed only on part of the exposed portion of the first S/D region 182a. Thus, part of the exposed portion of the first S/D region 182a is not covered by the mask 186 and left unprotected. The border of the mask 186 is over the first S/D region 182a. In some embodiments, in order to make sure that the second S/D region 182b is not covered by the mask 186, a portion of the first S/D region 182a is also exposed. In some embodiments, the border may be located such that the mask 186 covers more than 10 percent of a total width of the exposed portion of the first S/D region 182a, such as more than 30 percent, such as more than 50 percent, such as more than 70 percent, such as more than 90 percent of the total width. As shown, the mask 186 extends beyond the first S/D region 182a from the ILD layer 168 to the border over the first S/D region 182a. The mask 186 is partly covering the exposed portion of the first S/D region 182a and thereby protecting only part of the first S/D region 182a from implantation. In FIG. 36, compared to FIG. 27 without the mask, because the mask 186 is expanded to cover part of the exposed portion of the first S/D region 182a, the first doped region 188a is smaller in width. In such embodiment, the smaller doped region 188a does not substantially affect the operation of the SRAM cell 10, while contact resistance of the second S/D region 182b, which is part of the pull-up transistor PUx, is substantially reduced. The depth and concentration of the first doped region 188a and the second doped region 188b may be controlled as described in more detail below.

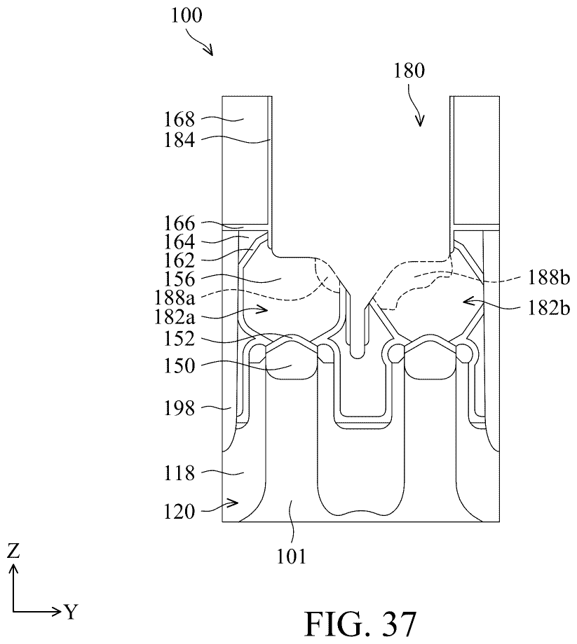

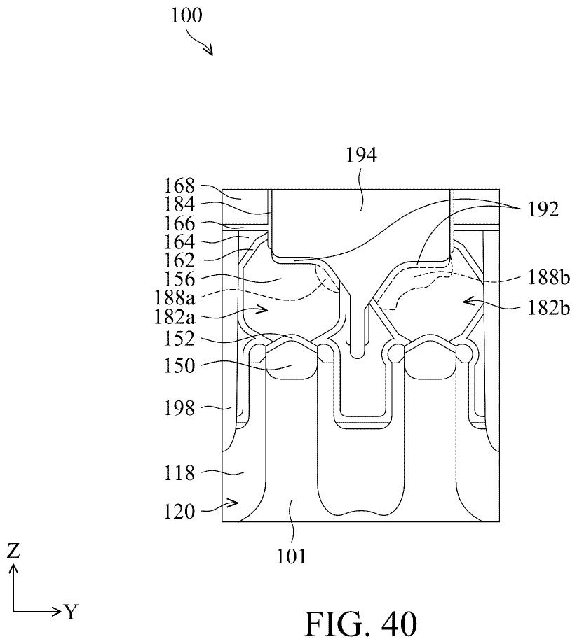

FIGS. 37-40 correspond to FIGS. 22-25, respectively, including removal of the mask 186, formation of the silicide layers 192, formation of the conductive contact 194, and the planarization operation. Thus, the final structure shown in FIG. 40 differs from FIG. 25 by the formation of the first doped region 188a.

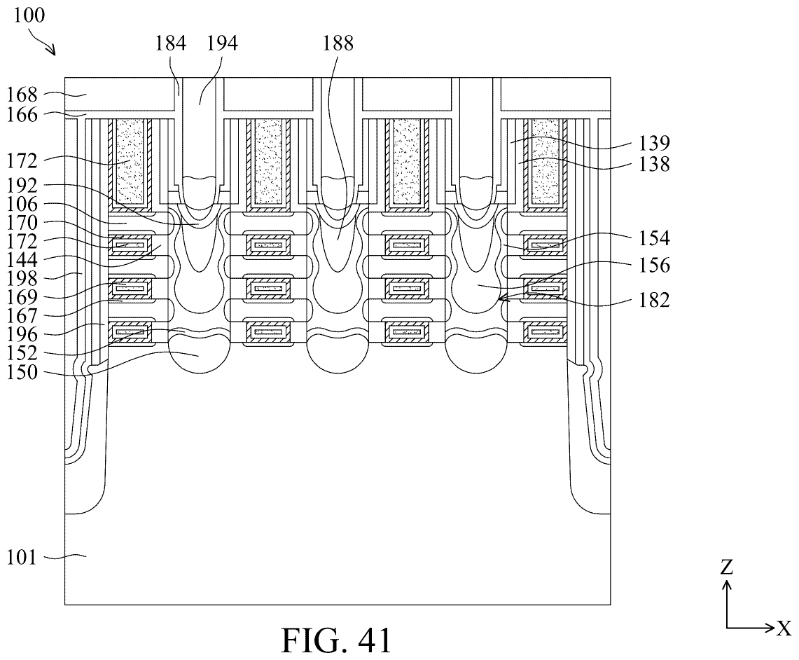

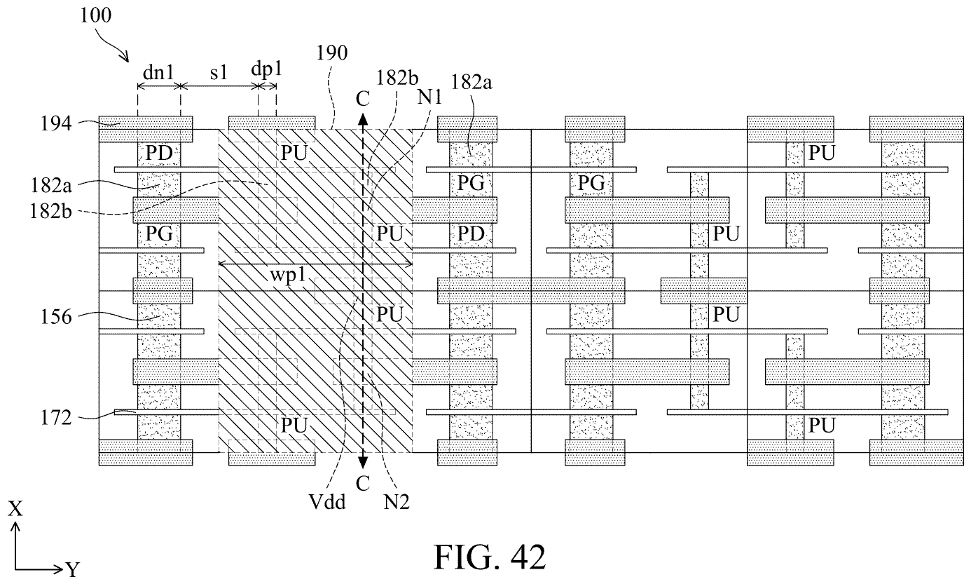

FIGS. 41-42 are a cross-sectional side view taken along line A-A of FIG. 6 and a schematic top view, respectively, of the semiconductor device structure 100 after formation of the conductive contacts 194 (see FIG. 25, for example), in accordance with some embodiments. As shown FIG. 42, the gate electrode layers 172, first S/D region 182a, second S/D region 182b, conductive contacts 194, and implant boundary 190 (inside dashed line) are illustrated. In some embodiments, the implant boundary 190 is defined by the mask 186 (see FIG. 21, for example) and corresponds to the unprotected regions outside the area of the mask 186 that are doped, as described earlier. As shown in FIG. 42, the implant boundary 190 corresponds to the p-type active area (e.g., two adjacent second S/D regions 182b) and extends into surrounding inactive areas (e.g., isolation regions 120) in the direction of the n-type active area (e.g., first S/D regions 182a) to about a mid-point between the p-type active area and the n-type active area. Thus, the implant boundary 190 extends partly across a spacing s1 between the first and second S/D regions 182a, 182b. In some embodiments, the implant boundary 190, in the X-direction, is not continuous, as shown in FIG. 42. Furthermore, example locations of pull-up transistors PU and pull-down transistors PD are identified. As described earlier, the first S/D region 182a can be n-type, and the second S/D region 182b can be p-type. As shown in FIG. 42, in some embodiments, a width dn1 of the first S/D region 182a is greater than a width dp1 of the second S/D region 182b. In some embodiments, a ratio of the width dn1 to the width dp1 is within a range between about 1.5 and about 2. As shown in FIG. 42, a ratio of a width wp1 of the implant boundary 190 to the width dp1 is within a range between about 6 and about 15. In some embodiments, the width wp1 is equal to the sum of twice the spacing s1 between the first and second S/D regions 182a, 182b and twice the width dp1 of the second S/D region 182b.

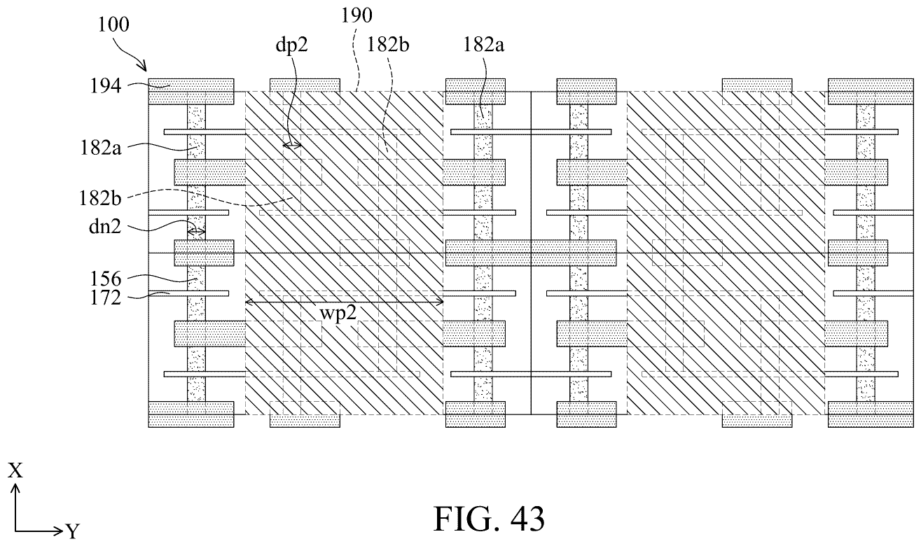

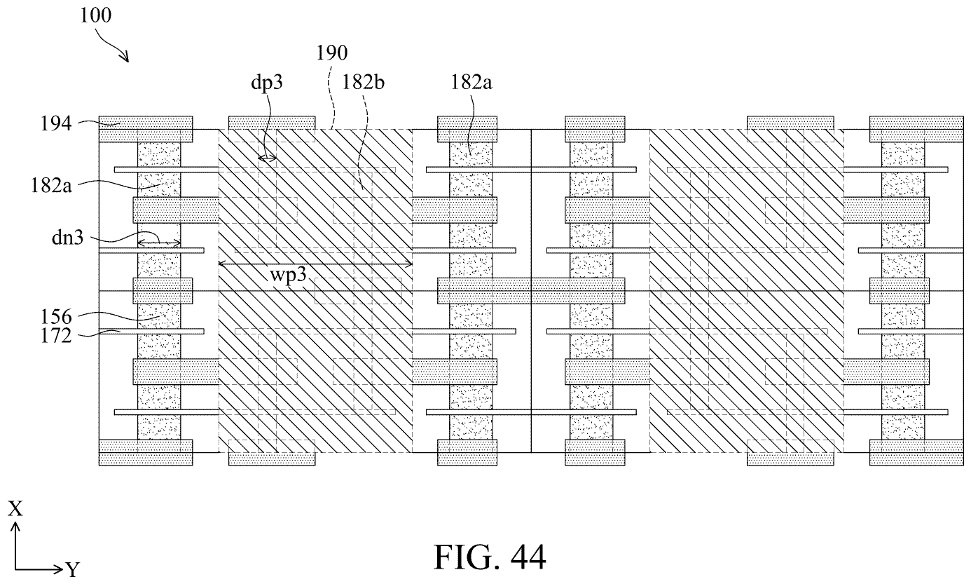

FIGS. 43-44 are schematic top views of alternative high density and high current cells, respectively, of the semiconductor device structure 100 of FIG. 42, in accordance with some embodiments. As shown in FIG. 43, a width dn2 of the first S/D region 182a is not greater than a width dp2 of the second S/D region 182b. For example, the width dn2 of the first S/D region 182a is about equal to the width dp2 of the second S/D region 182b. As used herein, the term “about” can mean +/−5%. In addition, the width dp2 is about equal to the width dp1. As shown in FIG. 43, a ratio of a width wp2 of the implant boundary 190 to the width dp2 is within a range between about 6 and about 15.

As shown in FIG. 44, a width dn3 of the first S/D region 182a is greater than a width dp3 of the second S/D region 182b. In some embodiments, a ratio of the width dn3 to the width dp3 is within a range between about 2 and about 4. In addition, the width dp3 is about equal to the width dp1. As shown in FIG. 44, a ratio of a width wp3 of the implant boundary 190 to the width dp3 is within a range between about 6 and about 15.

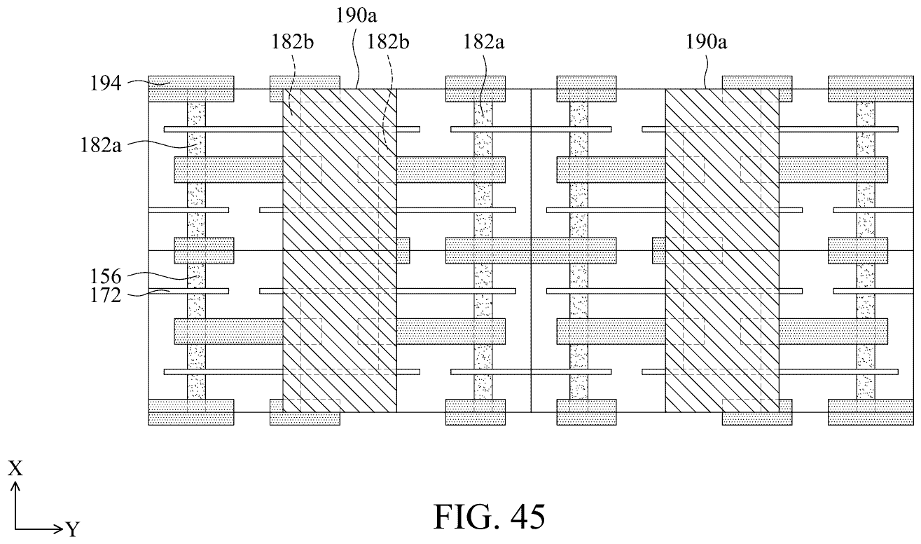

FIGS. 45-47 are schematic top views of alternative implant boundaries of the semiconductor device structure 100 of FIG. 42, in accordance with some embodiments. As shown in FIG. 45, the implant boundary 190a corresponds to the p-type active area only (e.g., two adjacent second S/D regions 182b) without extending into surrounding inactive areas (e.g., isolation regions 120) in the direction of the n-type active area (e.g., first S/D regions 182a). For example, in the Y-direction, the implant boundary 190a is aligned with opposite borders of the second S/D regions 182b. In the X-direction, the implant boundary 190a is not continuous.

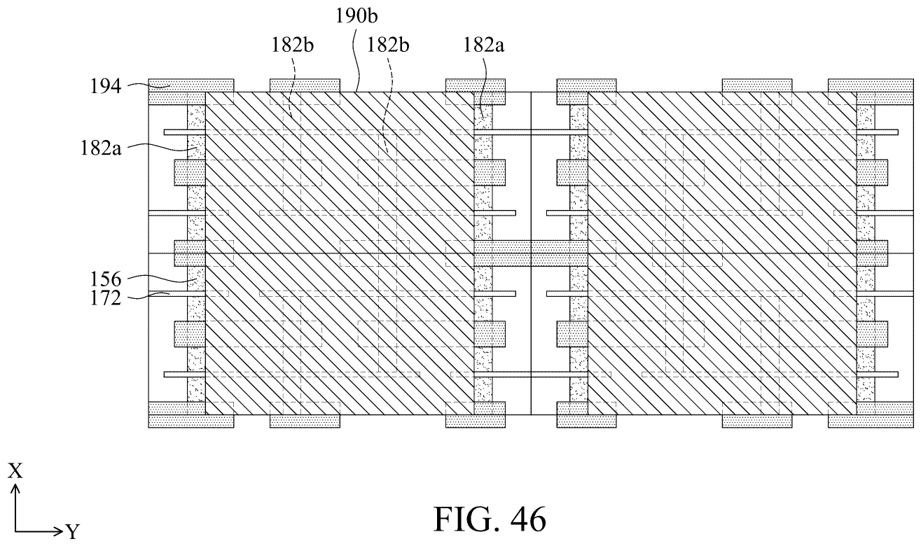

As shown in FIG. 46, the implant boundary 190b corresponds to the p-type active area (e.g., two adjacent second S/D regions 182b) and extends into surrounding inactive areas (e.g., isolation regions 120) in the direction of the n-type active area (e.g., first S/D regions 182a) beyond the mid-point and towards an outside border of the n-type active area. For example, in the Y-direction, the implant boundary 190b is aligned with outside borders of the first S/D regions 182b. In the X-direction, the implant boundary 190b is not continuous due to the cut OD.

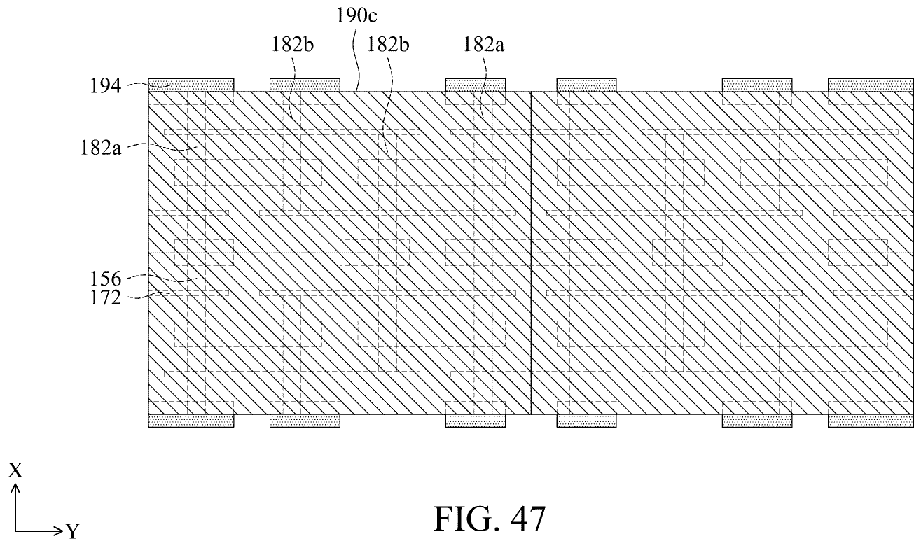

As shown in FIG. 47, the implant boundary 190c corresponds to the p-type active area (e.g., two adjacent second S/D regions 182b) and the n-type active area (e.g., first S/D regions 182a on either side of the p-type active area). For example, in the Y-direction, the implant boundary 190c extends completely over the first S/D regions 182b. In the X-direction, the implant boundary 190b is not continuous. This embodiment corresponds to the embodiment shown in FIGS. 26-30.

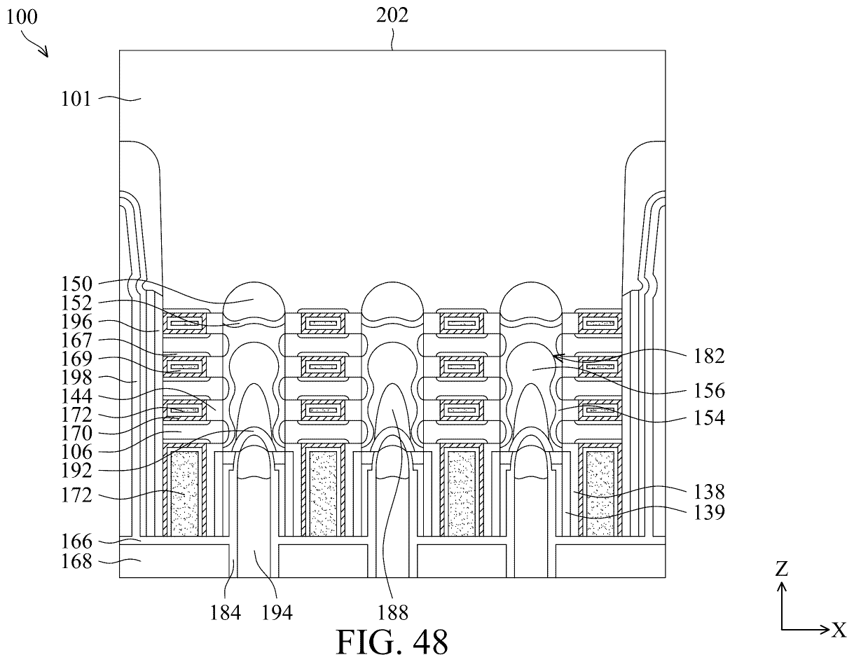

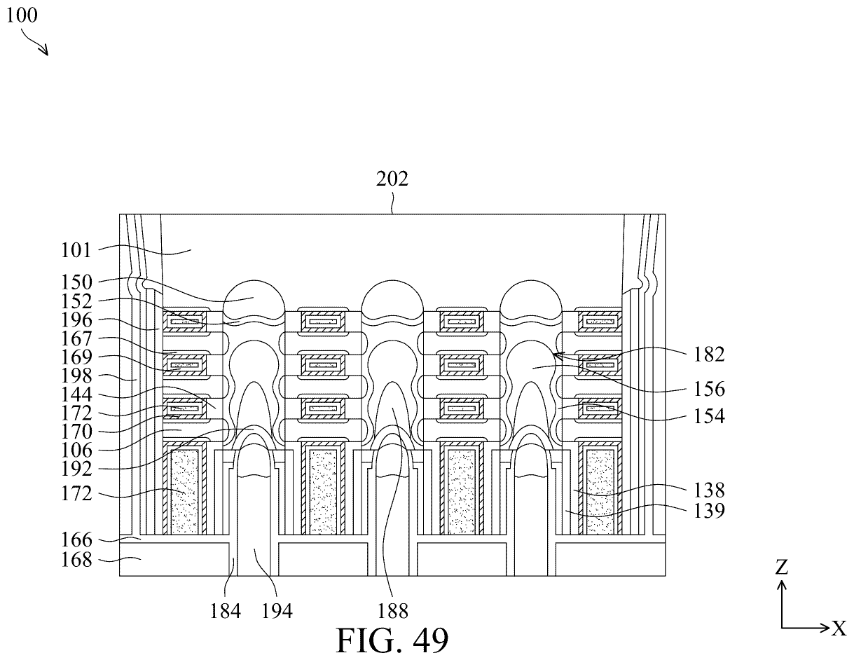

FIGS. 48-50 are cross-sectional side views of various stages of a backside process of manufacturing the semiconductor device structure 100 taken along line A-A of FIG. 6, in accordance with some embodiments. As shown in FIG. 48, after forming an interconnect structure on the front side, the semiconductor device structure 100 is flipped over and a backside thinning process is performed. Thus, FIG. 48 is the same as FIG. 41, except that the semiconductor device structure 100 is inverted. In some embodiments, a carrier wafer (not shown) may be bonded to a front side of the semiconductor device structure 100, and the semiconductor device structure 100 is flipped over so that a backside 202 (or “backside surface”) of the substrate 101, is facing up for backside processing. As shown in FIG. 49, the backside 202 of the substrate 101 may be thinned using a planarization or grinding operation, such as a CMP process. After the substrate 101 is thinned, the backside surface 202 includes the substrate 101 and isolation regions 120.

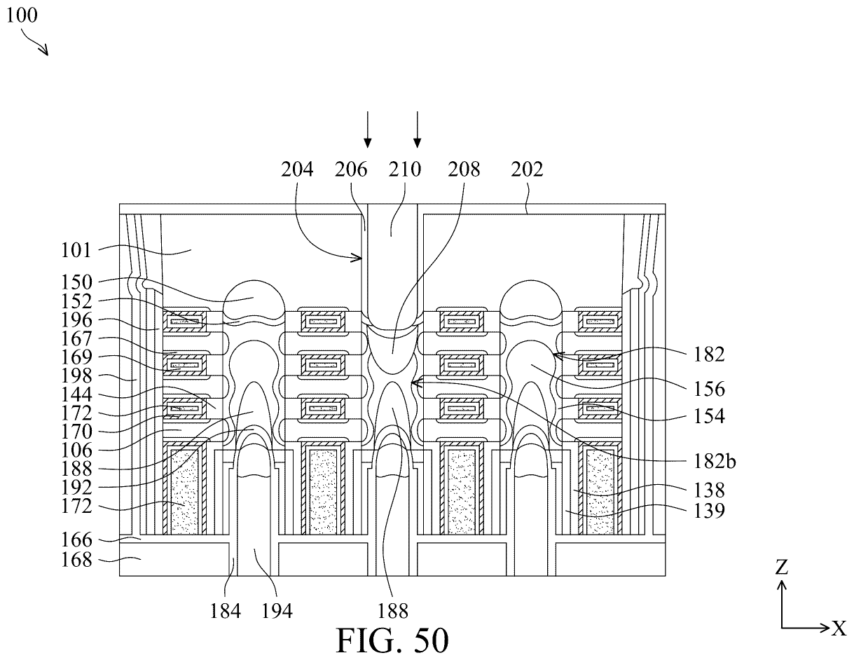

After the substrate 101 is thinned, one or more backside S/D contact openings are formed. For example, as shown in FIG. 50, an opening 204 is formed in the substrate 101, the first semiconductor material 150, and the dielectric layer 152 to expose the second S/D region 182b. The opening 204 may be formed by an etch process, such as a dry etch process, a wet etch process, or a combination thereof. A patterned mask (not shown) may be formed over the substrate 101, and the pattern of the patterned mask is transferred to the first semiconductor material 150 and the dielectric layer 152.

Next, as shown in FIG. 50, a liner 206 is formed on the substrate 101, the first semiconductor material 150, the dielectric layer 152, and the second S/D region 182b. The liner 206 may include any suitable material. In some embodiments, the liner 206 is a nitride layer, such as a silicon nitride layer. In some embodiments, the liner 206 includes the same material as the etch stop layer 166. The liner 206 may be formed by first forming a dielectric layer on the exposed surfaces of the semiconductor device structure 100, followed by an anisotropic etch process to remove portions of the dielectric layer formed on horizontal surfaces of the semiconductor device structure 100. For example, portions of the dielectric layer formed on the second S/D region 182b are removed by the anisotropic etch process.

Next, as shown in FIG. 50, a second implantation process is performed to implant a dopant to form a doped region 208 in the second S/D region 182b. In some embodiments, the dopant is a p-type dopant, such as boron. Performing the implantation process in the second S/D region 182b from both the front side and the backside can fine-tune dopant concentration across a greater depth and with respect to specific Si channels to improve PU device performance and gain SRAM read margin. The second implantation process can include aspects of the implantation process described in connection with FIG. 21, without limitation. The depth and concentration of the doped region 208 may be controlled as described in more detail below. After the second implantation process, a silicide layer may be formed on the exposed portion of the second S/D region 182b. The silicide layer may be formed by any suitable process including aspects of other silicide processes described herein.

Next, as shown in FIG. 50, a conductive contact 210 is formed in the opening 204. The conductive contact 210 is electrically connected to the second S/D region 182b. The conductive contact 210 may be electrically conductive and may include a material having one or more of Ru, Mo, Co, Ni, W, Ti, Ta, Cu, Al, TiN or TaN, and the conductive contact 210 may be formed by any suitable method, such as electro-chemical plating (ECP), or PVD. After forming the conductive contact 210, a planarization operation, such as a CMP process, may be performed. After the planarization operation, a backside interconnect structure may be formed.

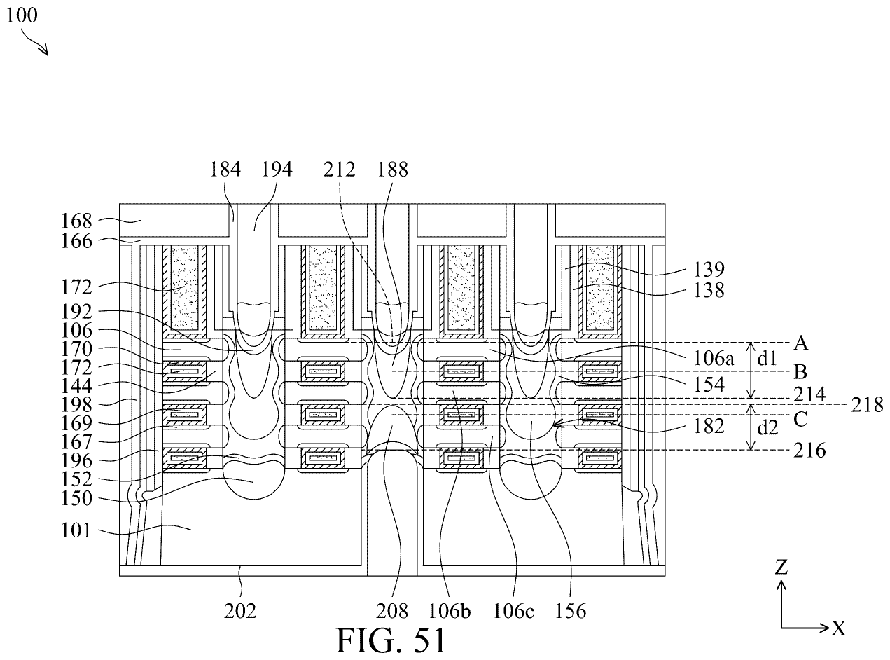

FIG. 51 is a cross-sectional side view of another stage of the semiconductor device structure 100 taken along line A-A of FIG. 6, in accordance with some embodiments. For example, FIG. 51 may show a portion of the device structure 100 along line C-C of FIG. 42 that includes a first node N1, Vdd node, and second node N2. In some embodiments, the Vdd node may be the voltage bus Vdd shown in FIG. 1. In some embodiments, the backside implantation process described in connection with FIG. 50 may be formed at the Vdd node (power connection) but not in the first and second nodes (signal connection). As shown in FIG. 51, after the backside process, the semiconductor device structure 100 is flipped back over to show the orientation that corresponds to FIG. 41. As shown in FIG. 51, the doped region 188, towards the front side, and doped region 208, closer to the backside, are formed at different depths in the second S/D region 182b. In some embodiments, the doped regions 188, 208 overlap (e.g., at least portions of the doped regions merge with each other). In some embodiments, a depth d1 of the doped region 188 is within a range between about 5 nm and about 25 nm (e.g., measured from top 212 to bottom 214 of the doped region 188). As shown in FIG. 51, the top 212 of the doped region 188 may be aligned with a top surface of a first semiconductor layer 106a nearest the front side. However, in some embodiments, the top 212 of the doped region 188 may be above or below the top surface of the first semiconductor layer 106a. In some embodiments, the bottom 214 of the doped region 188 may be located at a level between a top surface and a bottom surface of a second semiconductor layer 106b that is below the first semiconductor layer 106a. In some embodiments, the doped region 188 covers at least two semiconductor sheets, and the depth can be fine-tuned as sheet number changes. In some embodiments, a depth d2 of the doped region 208 is within a range between about 5 nm and about 25 nm (e.g., measured from bottom 216 to top 218 of the doped region 208). As shown in FIG. 51, the bottom 216 of the doped region 208 may be aligned with a bottom surface of a third semiconductor layer 106c nearest the backside 202. However, in some embodiments, the bottom 216 of the doped region 208 may be above or below the bottom surface of the third semiconductor layer 106c. In some embodiments, the top 218 of the doped region 208 may be located at a level between the second semiconductor layer 106b and the third semiconductor layer 106c. In some embodiments, the dopant has a concentration gradient from the third semiconductor material 156 to the second semiconductor material 154 that can achieve improved device performance. In some embodiments, using implant dosage split can fine-tune PG/PU threshold voltage (Vt) balance to improve SRAM margin.

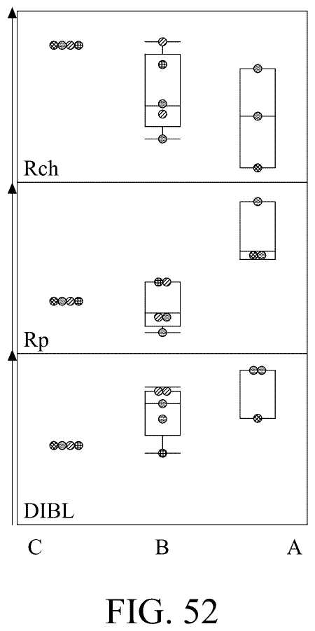

In some embodiments, there is a target concentration range for the dopant in the doped region 188 that is more advantageous, which is related to balancing contact resistance against drain-induced barrier loading (DIBL), which is a measure of the change of the threshold voltage to the drain voltage. For example, if the dopant concentration is greater than the target range, even though the contact resistance is improved, the DIBL is negatively affected. The dopant concentration from implantation is dependent on depth (e.g., forming a gradient along the depth d1). Likewise, the implant conditions (e.g., energy, dose, etc.) can be changed depending on the range of depths being treated. For example, to implant dopant in a shallow region starting at the top 212 of the doped region 188 (e.g., from line A to line B), the implantation energy may be within a range between about 0.6 keV and about 1 keV and an implantation dosage may be within a range between about 1×10¹⁵ cm⁻² and about 8×10¹⁵ cm⁻². Continuing this example, to implant dopant in a deeper region that is adjacent to and below the shallow region (e.g., from line B to line C), a higher implantation energy is needed, such as within a range between about 1 keV and about 1.3 keV and implantation dosage may be the same as before. In some embodiments, there is a target implantation depth that is more advantageous, which may be represented in terms of projected range (Rp), which is the average depth of the implanted ions. FIG. 52 illustrates test results for channel resistance (Rch) and DIBL for different implantation depths (extending to lines A, B, or C), which are indicated by higher to lower values of Rp, in accordance with some embodiments. In FIG. 52, lower Rch values (indicating lower resistance) and lower DIBL values are desirable. As shown in FIG. 52, implantation depth near line B represents a sweet spot that balances trade-offs between Rch and DIBL. For example, at implant depths near line B, there is a moderate reduction in Rch with minimal DIBL impact. In contrast to that result, DIBL impact is negative at implant depths near line A, and Rch improvement is minimal at implant depths near line C, both due to effects of dopant diffusion between the S/D region and the channel. Results that can be achieved, via the implantation processes described herein, include increase to threshold voltage (Vt) by 15% or more, decrease to Rch by 13 ohm*μm or more, decrease to Rp by 8 ohm*μm or more, and decrease to sigma by 2 mV or more.

In some embodiments, chip level Vmax can improve by 50 mV to 150 mV due to improved performance of PU PMOS from the implantation process described herein. In some embodiments, average increase in Vmax after implantation is about 50 mV. In some other embodiments, average increase in Vmax after implantation is about 150 mV.

Embodiments of the present disclosure provide a semiconductor device structure and methods of forming the same. In some embodiments, an implantation process is performed to implant a dopant into a S/D region to achieve lower contact resistance in source/drain formation, to improve PU transistor performance, and to increase each of sigma, SRAM read margin, and Vmax. Embodiments of the present disclosure achieve certain advantages as described above.

In some embodiments, a method includes forming first and second semiconductor fins on a front side of a substrate, removing portions of the first and second semiconductor fins to expose first and second substrate portions, respectively, forming a first source/drain region over the first substrate portion, wherein the first source/drain region comprises an n-type epitaxial material, forming a second source/drain region over the second substrate portion, wherein the second source/drain region comprises a p-type epitaxial material, depositing a dielectric material over the first and second source/drain regions, forming an opening in the dielectric material to expose a portion of the first source/drain region and a portion of the second source/drain region, forming a mask on the exposed portion of the first source/drain region, performing an implantation process to implant a dopant in the second source/drain region, removing the mask, and depositing a conductive contact electrically connected to the first and second source/drain regions.

In some embodiments, a method includes forming first and second semiconductor fins on a front side of a substrate, removing portions of the first and second semiconductor fins to expose first and second substrate portions, respectively, forming a first source/drain region over the first substrate portion, wherein the first source/drain region comprises an n-type epitaxial material, forming a second source/drain region over the second substrate portion, wherein the second source/drain region comprises a p-type epitaxial material, depositing a dielectric material over the first and second source/drain regions, forming an opening in the dielectric material to expose the first and second source/drain regions, performing a first implantation process to form a first doped region in the second source/drain region, depositing a conductive contact electrically connected to the first and second source/drain regions, flipping over the substrate, forming an opening in the substrate to expose the second source/drain region, and performing a second implantation process to form a second doped region in the second source/drain region.

In some embodiments, a structure includes a first source/drain region disposed over a substrate, wherein the first source/drain region comprises a p-type semiconductor material and a p-type dopant, a second source/drain region adjacent the first source/drain region, wherein the second source/drain region comprises an n-type semiconductor material and the p-type dopant, and a gate electrode layer disposed adjacent the first and second source/drain regions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming first and second semiconductor fins on a front side of a substrate;
removing portions of the first and second semiconductor fins to expose first and second substrate portions, respectively;
forming a first source/drain region over the first substrate portion, wherein the first source/drain region comprises an n-type epitaxial material;
forming a second source/drain region over the second substrate portion, wherein the second source/drain region comprises a p-type epitaxial material;
depositing a dielectric material over the first and second source/drain regions;
forming an opening in the dielectric material to expose a portion of the first source/drain region and a portion of the second source/drain region;
forming a mask on the exposed portion of the first source/drain region;
performing an implantation process to implant a dopant in the second source/drain region;
removing the mask; and
depositing a conductive contact electrically connected to the first and second source/drain regions.

2. The method of claim 1, wherein the dopant is a p-type dopant.

3. The method of claim 2, wherein the dopant is boron.

4. The method of claim 1, wherein the mask is formed on a portion of the exposed portion of the second source/drain region.

5. The method of claim 1, further comprising forming first and second silicide layers on the first and second source/drain regions, respectively, prior to depositing the conductive contact.

6. The method of claim 5, further comprising depositing a contact etch stop layer on the first and second source/drain regions, and the dielectric material is deposited on the contact etch stop layer.

7. The method of claim 1, wherein each of the first and second semiconductor fins comprises a plurality of semiconductor layers.

8. The method of claim 7, further comprising forming a gate electrode layer surrounding a portion of each of the plurality of semiconductor layers.

9. A method, comprising:
forming first and second semiconductor fins on a front side of a substrate;
removing portions of the first and second semiconductor fins to expose first and second substrate portions, respectively;
forming a first source/drain region over the first substrate portion, wherein the first source/drain region comprises an n-type epitaxial material;
forming a second source/drain region over the second substrate portion, wherein the second source/drain region comprises a p-type epitaxial material;
depositing a dielectric material over the first and second source/drain regions;
forming an opening in the dielectric material to expose the first and second source/drain regions;
performing a first implantation process to form a first doped region in the second source/drain region;
depositing a conductive contact electrically connected to the first and second source/drain regions;
flipping over the substrate;
forming an opening in the substrate to expose the second source/drain region; and
performing a second implantation process to form a second doped region in the second source/drain region.

10. The method of claim 9, wherein each of the first and second semiconductor fins comprises a plurality of semiconductor layers disposed adjacent the second source/drain region.

11. The method of claim 10, wherein the plurality of semiconductor layers includes a first semiconductor layer, a second semiconductor layer disposed over the first semiconductor layer, and a third semiconductor layer disposed over the second semiconductor layer.

12. The method of claim 11, wherein a bottom of the first doped region is located at a level between a top surface and a bottom surface of the second semiconductor layer.

13. The method of claim 12, wherein a top of the second doped region is located at a level between the second semiconductor layer and the third semiconductor layer.

14. The method of claim 11, wherein the first and second doped regions overlap in the second source/drain region.

15. The method of claim 9, wherein an implantation energy of the first and second implantation processes is within a range between about 0.6 keV and 1.3 keV.

16. A structure, comprising:
a first source/drain region disposed over a substrate, wherein the first source/drain region comprises a p-type semiconductor material and a p-type dopant;
a second source/drain region adjacent the first source/drain region, wherein the second source/drain region comprises an n-type semiconductor material and the p-type dopant; and
a gate electrode layer disposed adjacent the first and second source/drain regions.

17. The structure of claim 16, wherein the p-type semiconductor material comprises SiGe, the n-type semiconductor material comprises Si, and the p-type dopant comprises boron.

18. The structure of claim 16, wherein the first source/drain region further comprises a first doped region disposed at a top portion of the first source/drain region, a second doped region disposed at a bottom portion of the first source/drain region, and a third doped region between the first and second doped regions, wherein a dopant concentration of the third doped region is substantially less than dopant concentrations of the first and second doped regions.

19. The structure of claim 18, further comprising a first conductive contact electrically connected to the first source/drain region and a second conductive contact electrically connected to the first source/drain region.

20. The structure of claim 19, wherein the first conductive contact is disposed adjacent the first doped region, and the second conductive contact is disposed adjacent the second doped region.
